(19) United States
(12) Patent Application Publication
(10) Pub. No.: US 2024/0250103 A1
(43) Pub. Date: Jul. 25, 2024

(54) IMAGE SENSOR

(71) Applicant: SAMSUNG ELECTRONICS CO., LTD., SUWON-SI (KR)

(72) Inventors: SEONOK KIM, Suwon-si (KR); KWANYOUNG OH, Suwon-si (KR); HYUNGCHAE KIM, Suwon-si (KR); DONGYOUNG JANG, Suwon-si (KR)

(21) Appl. No.: 18/395,827

(22) Filed: Dec. 26, 2023

(30) Foreign Application Priority Data
Jan. 25, 2023 (KR) 10-2023-0009728

(51) Int. Cl. H01L 27/146; H04N 25/63

(52) U.S. Cl. CPC H01L 27/1463; H01L 27/14612; H01L 27/14621; H01L 27/14627; H01L 27/14636; H04N 25/63

(57) ABSTRACT

An image sensor includes a substrate including a pixel section and a separation pattern disposed in the substrate and surrounding the pixel section. The separation pattern includes a first sub-separation pattern that extends in a first direction, and a second sub-separation pattern that extends in a second direction that intersects the first direction. The pixel section includes a device isolation pattern that defines an active region in the pixel section, and at least one gate pattern on the active region. The gate pattern extends along a third direction from the first sub-separation pattern through the active region and the device isolation pattern to the second sub-separation pattern. The third direction intersects the first direction and the second direction. The gate pattern has a first surface and a second surface that are opposite to each other. The first surface extends linearly from the first sub-separation pattern to the second sub-separation pattern.

### CROSS-REFERENCE TO RELATED APPLICATION

This application claims priority under 35 U.S.C § 119 to Korean Patent Application No. 10-2023-0009728, filed on Jan. 25, 2023 in the Korean Intellectual Property Office, the disclosure of which is incorporated by reference in its entirety herein.

### 1. TECHNICAL FIELD

The present inventive concepts relate to an image sensor, and more particularly, to an image sensor including a driver transistor.

### 2. DISCUSSION OF RELATED ART

An image sensor is a device that converts optical images into electrical signals. Image sensors include a charge coupled device (CCD) type and a complementary metal oxide semiconductor (CMOS) type. A CMOS type image sensor (CIS) has a plurality of two-dimensionally arranged pixels. Each of the pixels includes a photodiode. The photodiode converts incident light into electrical signals.

With the advancement of the electronics industry, there has been an increase in the number of a plurality of two-dimensionally arranged pixels and a reduction in size of each of the pixels. Research is being conducted to effectively form elements that are disposed on each of the pixels to provide a pixel circuit.

### SUMMARY

Some embodiments of the present inventive concepts provide an image sensor capable of reducing noise generated from pixels.

Some embodiments of the present inventive concepts provide an image sensor having increased reliability.

According to an embodiment of the present inventive concepts, An image sensor includes a substrate that has a pixel section. A separation pattern is disposed in the substrate. The separation pattern surrounds the pixel section. The separation pattern includes a first sub-separation pattern that extends in a first direction parallel to an upper surface of the substrate. A second sub-separation pattern extends in a second direction that intersects the first direction and is parallel to the upper surface of the substrate. The pixel section includes a device isolation pattern that defines an active region in the pixel section. At least one gate pattern is on the active region. The at least one gate pattern extends along a third direction from the first sub-separation pattern through the active region and the device isolation pattern to the second sub-separation pattern. The third direction intersects the first direction and the second direction and is parallel to the upper surface of the substrate. The at least one gate pattern has a first surface and a second surface that are opposite to each other. The first surface extends linearly from the first sub-separation pattern to the second sub-separation pattern.

According to an embodiment of the present inventive concepts, an image sensor includes a pixel section. The pixel section includes an active region in the pixel section. The active region includes a first impurity region and a second impurity region. A gate pattern is on the active region. The gate pattern has a first surface and a second surface that are opposite to each other. The gate pattern is between the first impurity region and the second impurity region. The first surface is close to the first impurity region and extends linearly. An area of the first impurity region is less than an area of the second impurity region.

According to an embodiment of the present inventive concepts, an image sensor includes a substrate that includes a plurality of pixel sections. A separation pattern is in the substrate and positioned between adjacent pixels of the plurality of pixel sections. The separation pattern includes a first sub-separation pattern that extends in a first direction parallel to an upper surface of the substrate. A second sub-separation pattern extends in a second direction that intersects the first direction and is parallel to the upper surface of the substrate. The plurality of pixel sections include a first pixel section and a second pixel section that are adjacent to each other in the first direction. A third pixel section is adjacent to the first pixel section in the second direction; A fourth pixel section is adjacent to the second pixel section in the second direction and adjacent to the third pixel section in the first direction. Each of the first to fourth pixel sections includes a device isolation pattern that defines an active region in the first to fourth pixel sections. A transistor that corresponds to each of the first to fourth pixel sections. The active region includes a first impurity region and a second impurity region spaced apart from each other. The active region comprises first to fourth active regions in the first to fourth pixel sections, respectively. The transistor includes the first impurity region. The second impurity region. A gate pattern between the first impurity region and the second impurity region. The gate pattern comprises first to fourth gate patterns disposed in the first to fourth pixel sections, respectively. The first gate pattern and the fourth gate pattern extend along a third direction from the first sub-separation pattern to the second sub-separation pattern. The third direction intersects each of the first direction and the second direction and is parallel to the upper surface of the substrate. The second gate pattern and the third gate pattern extend along a fourth direction from the second sub-separation pattern to the first sub-separation pattern. The fourth direction intersects the first to third directions and is parallel to an upper surface of the substrate. The first to fourth gate patterns are in direct contact with each other on the separation pattern. A combination of the first to fourth gate patterns in direct contact with each other has an inner surface having a rhombic shape and an outer surface having an octagonal shape.

### BRIEF DESCRIPTION OF DRAWINGS

FIG. 1 illustrates a simplified block diagram showing an image sensor according to an embodiment of the present inventive concepts.

FIG. 2 illustrates a circuit diagram showing a pixel of an image sensor according to an embodiment of the present inventive concept.

FIG. 3 illustrates a plan view showing an image sensor according to an embodiment of the present inventive concept.

FIG. 4 illustrates a cross-sectional view taken along line I-I′ of FIG. 3 according to an embodiment of the present inventive concept.

FIG. 5 illustrates a cross-sectional view taken along line I-I′ of FIG. 3, showing an image sensor according to an embodiment of the present inventive concept.

FIG. 6 illustrates a cross-sectional view taken along line II-II′ of FIG. 3 according to an embodiment of the present inventive concept.

FIG. 7 illustrates an enlarged plan view of portion M depicted in FIG. 3, showing a pixel of an image sensor according an embodiment of the present inventive concept.

FIG. 8A illustrates a cross-sectional view taken along line A-A′ of FIG. 7 according to an embodiment of the present inventive concept.

FIG. 8B illustrates a cross-sectional view taken along line B-B′ of FIG. 7 according to an embodiment of the present inventive concept.

FIG. 9 illustrates a plan view of area M depicted in FIG. 3, showing a pixel different from that of an image sensor according to an embodiment of the present inventive concept.

FIG. 10 illustrates a plan view of area M depicted in FIG. 3, showing a pixel of an image sensor according to an embodiment of the present inventive concept.

FIG. 11A illustrates a cross-sectional view taken along line A-A′ of FIG. 10 according to an embodiment of the present inventive concept.

FIG. 11B illustrates a cross-sectional view taken along line B-B′ of FIG. 10 according to an embodiment of the present inventive concept.

FIG. 11C illustrates a cross-sectional view taken along line C-C′ of FIG. 10 according to an embodiment of the present inventive concept.

FIGS. 12A and 12B illustrate plan views of area M depicted in FIG. 3, showing a pixel different from that of an image sensor according to some embodiments of the present inventive concepts.

FIGS. 13 and 14 illustrate plan views showing pixels of an image sensor according to some embodiments of the present inventive concepts.

### DETAILED DESCRIPTION OF EMBODIMENTS

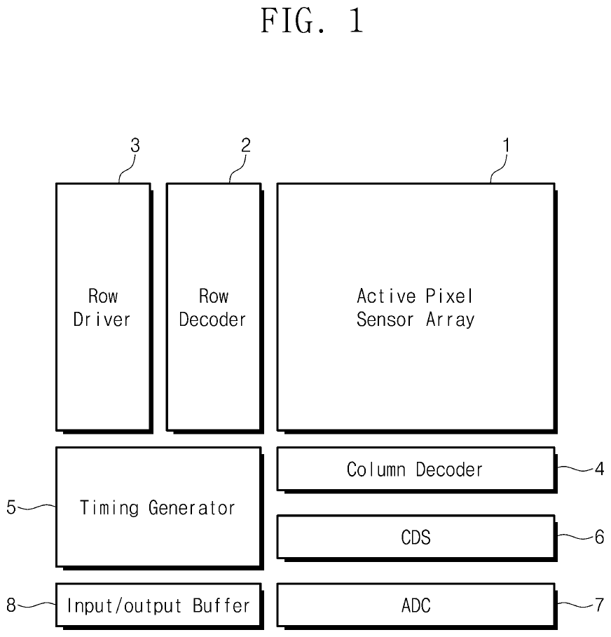

FIG. 1 illustrates a simplified block diagram showing an image sensor according to some embodiments of the present inventive concepts.

Referring to FIG. 1, an image sensor may include an active pixel sensor array 1, a row decoder 2, a row driver 3, a column decoder 4, a timing generator 5, a correlated double sampler (CDS) 6, an analog-to-digital converter (ADC) 7, and an input/output (I/O) buffer 8.

The active pixel sensor array 1 may include a plurality of two-dimensionally arranged pixels, each of the pixels may convert optical signals into electrical signals. In an embodiment, the active pixel sensor array 1 may be driven by a plurality of driving signals, such as a pixel selection signal, a reset signal, and a charge transfer signal, which are provided from the row driver 3. In addition, the correlated double sampler 6 may be provided with the electrical signals which are converted by the active pixel sensor array 1.

The row driver 3 may provide the active pixel sensor array 1 with several driving signals for driving several pixels in accordance with a decoded result obtained from the row decoder 2. In a case that the plurality of pixels are arranged in a matrix shape, the driving signals may be provided for each row.

The timing generator 5 may provide timing and control signals to the row decoder 2 and the column decoder 4.

The correlated double sampler 6 may receive the electrical signals generated from the active pixel sensor array 1, and may hold and sample the received electrical signals. The correlated double sampler 6 may perform a double sampling operation to sample a specific noise level and a signal level of the electrical signal, and then may output a difference level corresponding to a difference between the noise and signal levels.

The analog-to-digital converter 7 may convert analog signals, which correspond to the difference level received from the correlated double sampler 6, into digital signals and then output the converted digital signals.

In an embodiment, the input/output buffer 8 may latch the digital signals and then sequentially output the latched digital signals to an image signal processing unit in response to the decoded result obtained from the column decoder 4.

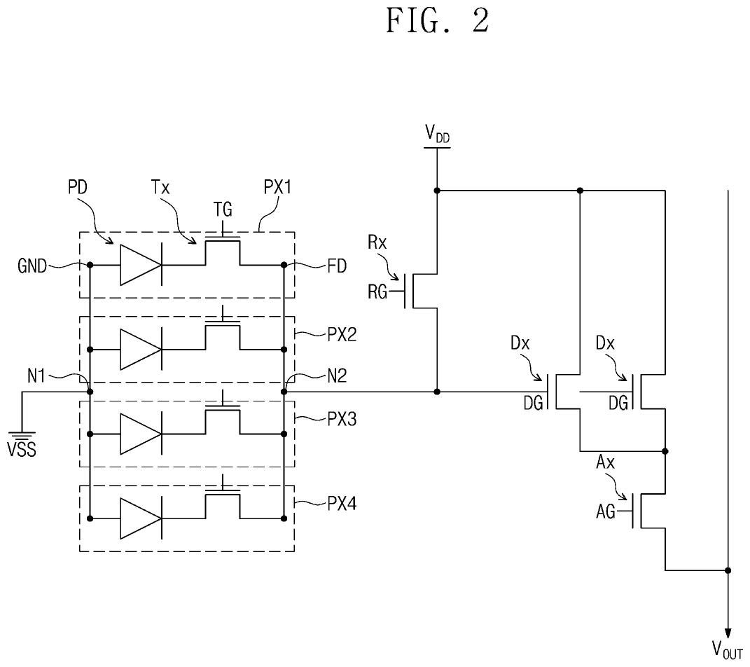

FIG. 2 illustrates a circuit diagram showing a pixel of an image sensor according to some embodiments of the present inventive concepts.

Referring to FIG. 2, an image sensor may include first to fourth pixels PX1 to PX4. Each of the first to fourth pixels PX1 to PX4 may include a ground region GND, a photoelectric conversion region PD, a transfer transistor Tx, and a floating diffusion region FD.

In an embodiment, the ground region GND may include a p-type impurity region. In an embodiment, a ground voltage VSS may be applied in common through a first node N1 to the ground regions GND of the first to fourth pixels PX1 to PX4.

In an embodiment, the photoelectric conversion region PD may be a photodiode that includes an n-type impurity region and a p-type impurity region. The floating diffusion region FD may include an n-type impurity region. The floating diffusion section FD may serve as a drain of the transfer transistor Tx.

The floating diffusion regions FD of the first to fourth pixels PX1 to PX4 may be connected in common to a second node N2. The second node N2 that the floating diffusion regions FD of the first to fourth pixels PX1 to PX4 are connected to may be connected to a reset transistor Rx.

The second node N2 may also be electrically connected to driver gates DG of a plurality of driver transistors Dx. For example, the driver transistors Dx may be source follower transistors. The driver transistor Dx may be connected to a selection transistor Ax.

An operation of the image sensor will be explained below with reference to FIG. 2. In an embodiment, a power voltage V_{DD} may be applied to a drain of the reset transistor Rx and drains of the driver transistors Dx under a light-blocked state. The reset transistor Rx may be turned on to discharge charges that remain on the floating diffusion region FD. Thereafter, when the reset transistor Rx is turned off and external light is incident on the photoelectric conversion region PD, electron-hole pairs may be generated in the photoelectric conversion region PD. Holes may be transferred to and accumulated on a p-type impurity region of the photoelectric conversion region PD, and electrons may be transferred to and accumulated on an n-type impurity region of the photoelectric conversion region PD. When the transfer transistor Tx is turned on, charges such as electrons and holes may be transferred to and accumulated on the floating diffusion region FD. A gate bias of the driver transistors Dx may change in proportion to an amount of the accumulated charges, and this may bring about a variation in source potential of the driver transistors Dx. In an embodiment, when the selection transistor Ax is turned on, charges may be read out as signals transmitted through a column line.

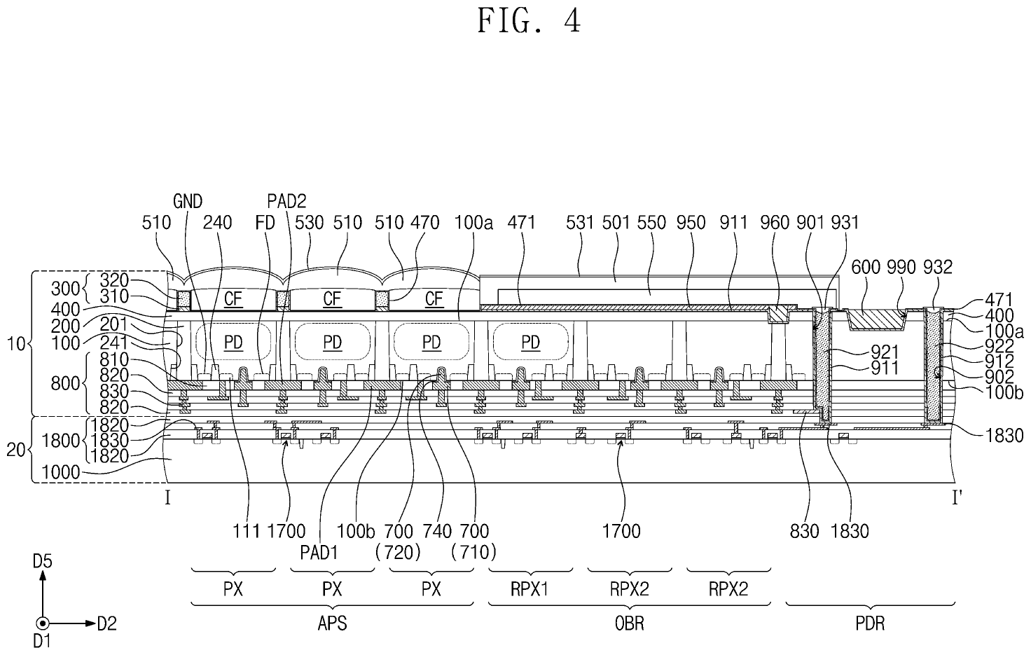

A wiring line may be electrically connected to at least one selected from a transfer gate TG, a driver gate DG, a reset gate RG, and a selection gate AG. The wiring line may apply the power voltage V_{DD} to the drain of the reset transistor Rx and the drains of the driver transistors Dx. The wiring line may include a column line connected to the selection transistor Ax. The wiring line may include a first conductive structure 830 which will be discussed in FIG. 4. An output voltage V_{OUT} may be applied to the selection transistor through the wiring line. A signal by electric charge is read into the wiring line by the applied output voltage V_{OUT}.

FIG. 2 depicts by way of example the first to fourth pixels PX1 to PX4 that share the first node N1 and the second node N2. However, embodiments of the present inventive concepts are not necessarily limited thereto.

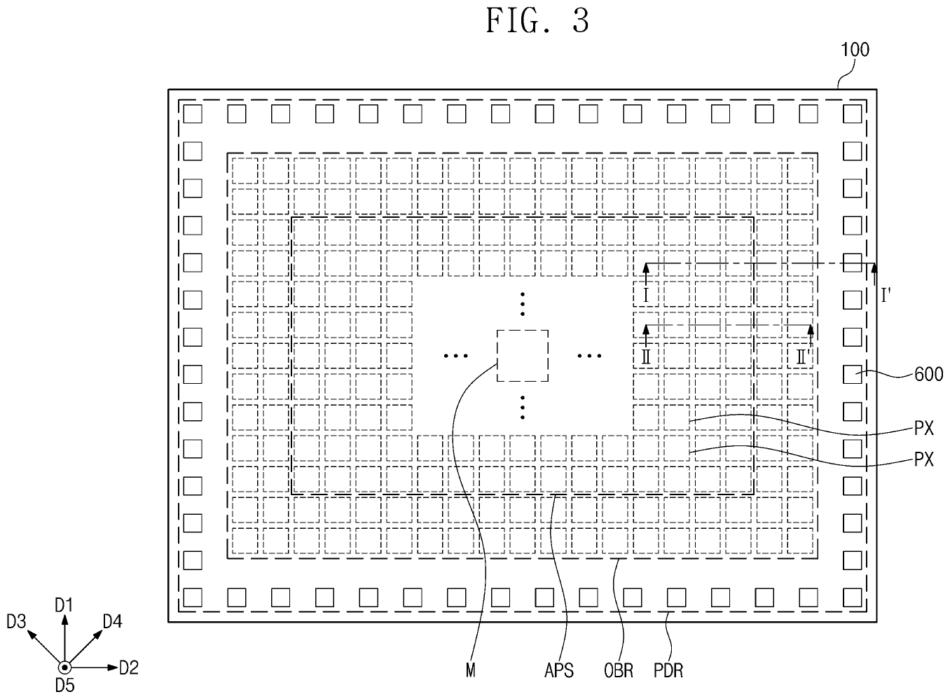

FIG. 3 illustrates a plan view showing an image sensor according to some embodiments of the present inventive concepts. FIG. 4 illustrates a cross-sectional view taken along line I-I′ of FIG. 3.

Referring to FIGS. 3 and 4, an image sensor may include a sensor chip 10. The sensor chip 10 may include a first substrate 100, a first wiring layer 800, a dielectric layer 400, a protective layer 470, color filters CF, a fence pattern 300, and a microlens layer 500.

When viewed in a plan view, the first substrate 100 may include a pixel array zone APS, an optical black zone OBR, and a pad zone PDR. In an embodiment, the pixel array zone APS may be disposed on a central portion of the first substrate 100 in the plan view. The pixel array zone APS may include a plurality of pixel sections PX. The pixel discussed with reference to FIG. 1 may be disposed in each of the pixel sections PX of the first substrate 100. For example, components of the pixel depicted in FIG. 1 may be disposed in each of the pixel sections PX. The pixel sections PX may output photoelectric signals from incident light.

The pixel sections PX may be two-dimensionally arranged in rows and columns. The rows may be parallel to a second direction D2. The columns may be parallel to a first direction D1.

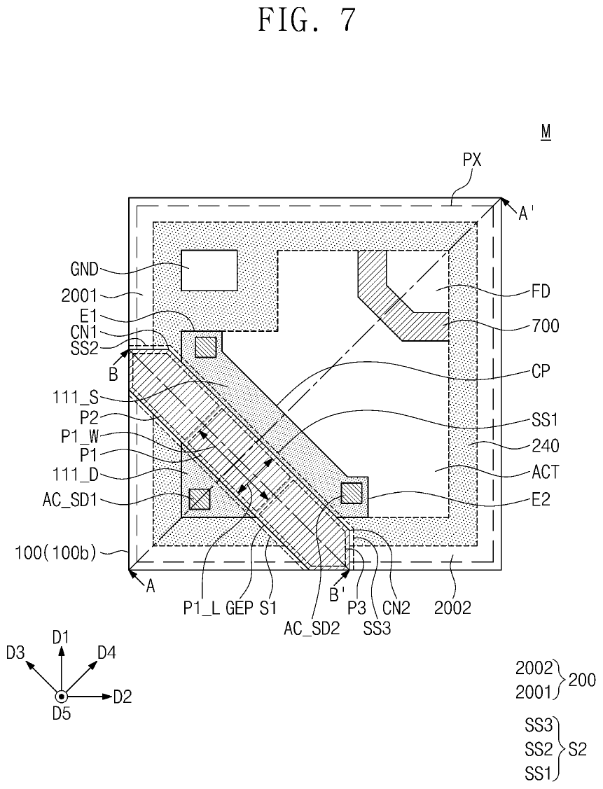

Referring still to FIGS. 3 and 7, in an embodiment the second direction D2 may be parallel to a first surface 100a of the first substrate 100. The first direction D1 may be parallel to the first surface 100a of the first substrate 100 and may intersect the second direction D2. For example, in an embodiment the second direction D2 may be substantially orthogonal to the first direction D1. However, embodiments of the present disclosure are not necessarily limited thereto. A third direction D3 may intersect both of the first direction D1 and the second direction D2. A fourth direction D4 may intersect the third direction D3, and in an embodiment may be substantially orthogonal to the third direction D3. However, embodiments of the present disclosure are not necessarily limited thereto. A fifth direction D5 may be perpendicular to all of the first direction D1, the second direction D2, the third direction D3, and the fourth direction D4. For example, in an embodiment the fifth direction D5 may be substantially perpendicular to the first surface 100a of the first substrate 100. However, embodiments of the present disclosure are not necessarily limited thereto

The pad zone PDR may surround the pixel array zone APS, while being positioned on an edge portion of the first substrate 100. The pad zone PDR may be provided with pads PAD thereon. The pads PAD may externally output electrical signals generated from the pixel sections PX. Alternatively, external electrical signals or voltages may be transferred through the pads PAD to the pixel sections PX. As the pad zone PDR is disposed on the edge portion of the first substrate 100, the pads PAD may be easily coupled to an external apparatus. The optical black zone OB will be described below. The following description will focus on the pixel array zone APS of the sensor chip 10 included in the image sensor.

The first substrate 100 may have a first surface 100a and a second surface 100b that are opposite to each other. The first surface 100a may be a rear surface of the first substrate 100, and the second surface 100b may be a front surface of the first substrate 100. The first substrate 100 may receive light on the first surface 100a. In an embodiment, the first substrate 100 may be a semiconductor substrate or a silicon-on-insulator (SOI) substrate. In an embodiment, the semiconductor substrate may be, for example, a silicon substrate, a germanium substrate, or a silicon-germanium substrate. The first substrate 100 may further include a III-group element. The III-group element may be an impurity having a first conductivity type. For example, the first substrate 100 may have the first conductivity type, for example, p-type. For example, impurities having the first conductivity type may include one or more compound selected from aluminum (Al), boron (B), indium (In), and gallium (Ga). However, embodiments of the present disclosure are not necessarily limited thereto.

The first substrate 100 may include a plurality of photoelectric conversion regions PD therein. The photoelectric conversion regions PD may be positioned between the first surface 100a and the second surface 100b of the first substrate 100 (e.g., in the fifth direction D5). The photoelectric conversion regions PD may be correspondingly provided in the pixel sections PX of the first substrate 100. The photoelectric conversion region PD of FIG. 3 may be the same as the photoelectric conversion region PD of FIG. 1.

In an embodiment, the photoelectric conversion region PD may further include a V-group element. The V-group element may be an impurity having a second conductivity type. For example, the photoelectric conversion region PD may be an impurity region having the second conductivity type. The second conductivity type may be an n-type different from the first conductivity type. In an embodiment, the impurities having the second conductivity type may include one or more compounds selected from phosphorus, arsenic, bismuth, and antimony. The photoelectric conversion region PD may be adjacent to the first surface 100a of the first substrate 100. The photoelectric conversion region PD may extend from the first surface 100a towards the second surface 100b.

The first substrate 100 may include a separation pattern 200 that defines the pixel sections PX. For example, the separation pattern 200 may be disposed between adjacent pixel sections PX. In an embodiment, the separation pattern 200 may be a pixel isolation pattern. The separation pattern 200 may be disposed in a first trench 201. The first trench 201 may be recessed from the second surface 100b (e.g., in the fifth direction D5) and extend towards the first surface 100a of the first substrate 100.

In an embodiment, the separation pattern 200 may be a deep trench isolation (DTI) layer. In an embodiment as shown in FIG. 4, the separation pattern 200 may penetrate the first substrate 100. However, embodiments of the present disclosure are not necessarily limited thereto. For example, in an embodiment of the separation pattern 200 may not penetrate the first substrate 100 and may be spaced apart from the first surface 100a of the first substrate 100. In an embodiment, a width of the separation pattern 200 adjacent to the second surface 100b may be greater than that of the separation pattern 200 adjacent to the first surface 100a. The separation pattern 200 will be discussed below.

The color filters CF may be correspondingly disposed on the pixel sections PX on the first surface 100a of the first substrate 100. For example, the color filters CF may be disposed on locations that correspond to the photoelectric conversion regions PD. For example, the color filters CF may overlap the photoelectric conversion regions PD (e.g., in the fifth direction D5). In an embodiment, each of the color filters CF may include one of a red filter, a blue filter, and a green filter. The color filters CF may constitute color filter arrays. For example, in an embodiment the color filters CF may be two-dimensionally arranged in Bayer pattern format.

However, embodiments of the present disclosure are not necessarily limited thereto and the colors of the color filters CF may vary. For example, in an embodiment the color filters CF may further include a white filter. For example, the color filters CF may include a red filter, a blue filter, a green filter, and a white filter that are two-dimensionally arranged.

The fence pattern 300 may be disposed on the separation pattern 200. For example, the fence pattern 300 may vertically overlap the separation pattern 200. The fence pattern 300 may be interposed between and separate two adjacent color filters CF. For example, the fence pattern 300 may physically and optically separate the color filters CF from each other.

The fence pattern 300 may have a planar shape that corresponds to that of the separation pattern 200. For example, the fence pattern 300 may have a grid shape. When viewed in a plan view, the fence pattern 300 may surround each of the pixel sections PX. The fence pattern 300 may surround each of the color filters CF. In an embodiment, the fence pattern 300 may include first segments and second segments. The first segments may extend parallel to the first direction D1 and may be spaced apart from each other in the second direction D2. The second segments may extend parallel to the second direction D2 and may be spaced apart from each other in the first direction D1. The second segments may intersect the first segments.

The fence pattern 300 may include a first fence pattern 310 and a second fence pattern 320. The first fence pattern 310 may be disposed between the dielectric layer 400 and the second fence pattern 320 (e.g., in the fifth direction D5). In an embodiment, the first fence pattern 310 may include a conductive material, such as one or more of metal and metal nitride. For example, the first fence pattern 310 may include one or more of titanium and titanium nitride.

The second fence pattern 320 may be disposed on the first fence pattern 310 (e.g., disposed directly thereon in the fifth direction D5). The second fence pattern 320 may include a different material from that of the first fence pattern 310. For example, the second fence pattern 320 may include an organic material. The second fence pattern 320 may include a material having a refractive index that is low and may have dielectric characteristics.

The dielectric layer 400 may be interposed between the first substrate 100 and the color filters CF (e.g., in the fifth direction D5) and between the separation pattern 200 and the fence pattern 300. The dielectric layer 400 may cover the first surface 100a of the first substrate 100 and a top surface of the separation pattern 200. The dielectric layer 400 may be a backside dielectric layer. In an embodiment, the dielectric layer 400 may include a bottom antireflective coating (BARC) layer. The dielectric layer 400 may include a plurality of layers. The layers may have different functions from each other.

In an embodiment, the dielectric layer 400 may include a first dielectric layer, a second dielectric layer, a third dielectric layer, a fourth dielectric layer, and a fifth dielectric layer that are sequentially stacked on the first surface 100a of the first substrate 100. The first dielectric layer may cover the first surface 100a of the first substrate 100. The first and second dielectric layers may be fixed charge layers. Each of the fixed charge layers may include a metal oxide layer and a metal fluoride layer. For example, the metal oxide layer may include oxygen having a content that is less than a stoichiometric ratio, and the metal fluoride layer may include fluorine having a content that is less than a stoichiometric ratio.

For example, the first dielectric layer may include metal oxide or metal fluoride that includes at least one metal selected from hafnium (Hf), zirconium (Zr), aluminum (Al), tantalum (Ta), titanium (Ti), yttrium (Y), and lanthanide. The second dielectric layer may include one of metal oxide and metal fluoride that are discussed in the example of the first dielectric layer. However, embodiments of the present disclosure are not necessarily limited thereto and the second dielectric layer may include a different material from that of the first dielectric layer. For example, the first dielectric layer may include aluminum oxide, and the second dielectric layer may include hafnium oxide.

Each of the first and second dielectric layers may have a negative fixed charge and may produce hole accumulation. The first and second dielectric layers may effectively reduce white spot and dark current of the first substrate 100. The second dielectric layer may have a thickness greater than that of the first dielectric layer.

The third dielectric layer may be disposed on the second dielectric layer. In an embodiment, the third dielectric layer may include a first silicon-containing material. The first silicon-containing material may include, for example, tetraethylorthosilicate (TEOS) or silicon oxide. The third dielectric layer may have good filling characteristics. The third dielectric layer may be formed by plasma enhanced chemical vapor deposition. However, embodiments of the present disclosure are not necessarily limited thereto. The third dielectric layer may have a thickness greater than that of the first dielectric layer and that of the second dielectric layer.

The fourth dielectric layer may be disposed on the third dielectric layer. The fourth dielectric layer may include a different material from that of the third dielectric layer. The fourth dielectric layer may include a second silicon-containing material, and the second silicon-containing material may be different from the first silicon-containing material. For example, in an embodiment the fourth dielectric layer may include silicon nitride. However, embodiments of the present disclosure are not necessarily limited thereto. The fourth dielectric layer may have a thickness greater than that of the third dielectric layer.

The fifth dielectric layer may be disposed between the fourth dielectric layer and the first fence pattern 310 and between the fourth dielectric layer and the color filters CF. The fifth dielectric layer may be in physical contact with a bottom surface of the first fence pattern 310. The fifth dielectric layer may be an adhesive layer or a capping layer. The fifth dielectric layer may include a high-k dielectric material or metal oxide. In an embodiment, the fifth dielectric layer may include the same material as that of the second dielectric layer. For example, the fifth dielectric layer may include hafnium oxide. The fifth dielectric layer may have a thickness greater than that of each of the first and second dielectric layers and less than that of each of the third and fourth dielectric layers.

However, embodiments of the present disclosure are not necessarily limited thereto and w 2qthe number of layers included in the dielectric layer 400 may be variously changed. For example, at least one of the first to fifth dielectric layers may be omitted.

The protective layer 470 may cover the dielectric layer 400 and the fence pattern 300. The protective layer 470 may include a high-k dielectric material and may have dielectric characteristics. For example, the protective layer 470 may include aluminum oxide or hafnium oxide. The protective layer 470 may include aluminum oxide. However, embodiments of the present inventive concepts are not necessarily limited thereto. The protective layer 470 may protect the photoelectric conversion regions PD of the first substrate 100 against external environment such as moisture.

The color filters CF may be disposed on the protective layer 470. The fence pattern 300 may separate the color filters CF from each other. In an embodiment, an uppermost surface of the color filter CF may be coplanar (e.g., in the fifth direction D5) with a top surface of the fence pattern 300. Alternatively, the uppermost surface of the color filter CF may be higher than the top surface of the fence pattern 300.

The microlens layer 500 may be provided on the first surface 100a of the first substrate 100. For example, the microlens layer 500 may be provided on the color filters CF. The protective layer 470 may be interposed between the second fence pattern 320 and the microlens layer 500.

The microlens layer 500 may include a plurality of convex microlenses 510. The microlenses 510 may be correspondingly disposed on positions that corresponds to the photoelectric conversions regions FD of the first substrate 100. For example, the microlenses 510 may be disposed on and correspond to the color filters CF. When viewed in a plan view, the microlenses 510 may be arranged along the first direction D1 and the second direction D2. Each of the microlenses 510 may protrude away from the first surface 100a of the first substrate 100. Each of the microlenses 510 may have a hemispheric cross-section. The microlenses 510 may concentrate incident light.

The microlens layer 500 may be transparent to light. The microlens layer 500 may include an organic material, such as a polymer. For example, the microlens layer 500 may include a photoresist material or a thermosetting resin.

A lens coating layer 530 may be disposed on the microlens layer 500. The lens coating layer 530 may be transparent. The lens coating layer 530 may conformally cover a top surface of the microlens layer 500. The lens coating layer 530 may protect the microlens layer 500.

The first substrate 100 may include a ground region GND, a floating diffusion region FD, and an impurity region 111 that are adjacent to the second surface 100b thereof. The ground region GND, the floating diffusion region FD, and the impurity region 111 may be disposed in each of the pixel sections PX. Each of the ground region GND, the floating diffusion region FD, and the impurity region 111 may have bottom surfaces that are vertically spaced apart from the photoelectric conversion region PD.

In an embodiment, the ground region GND may be heavily doped with impurities having the first conductivity type (e.g., p+ type). The floating diffusion region FD and the impurity region 111 may each be doped with impurities having the second conductivity type (e.g., n-type).

The impurity region 111 may be an active region for operation of a transistor. The impurity region 111 may include a source/drain region of at least one compound selected from the reset transistor Rx, the driver transistor Dx, and the selection transistor Ax that are discussed with reference to FIG. 2.

A device isolation pattern 240 may be disposed adjacent to the second surface 100b of the first substrate 100. The device isolation pattern 240 may define an active region in the pixel section PX. For example, in the pixel section PX, the device isolation pattern 240 may define the ground region GND, the floating diffusion region FD, and the impurity region 111.

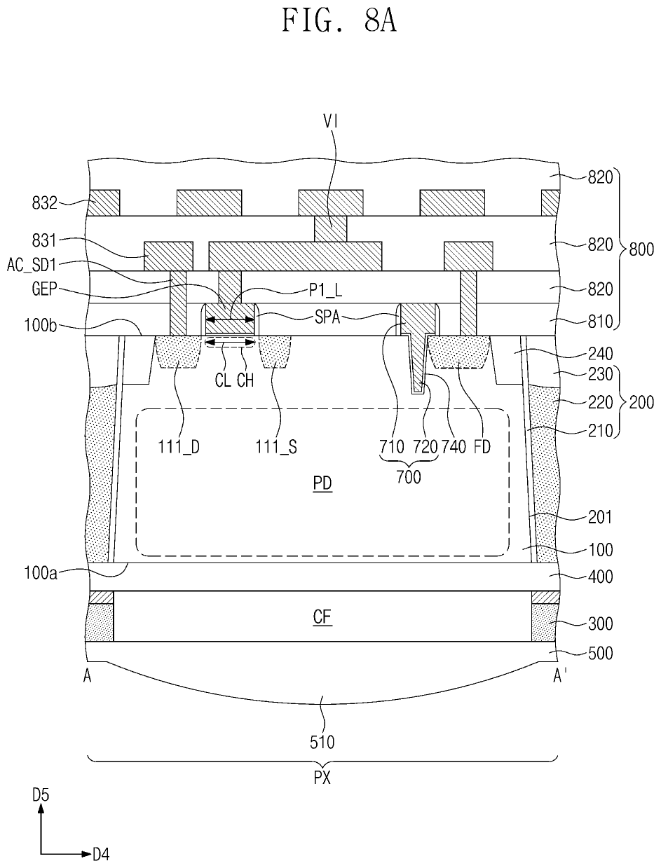

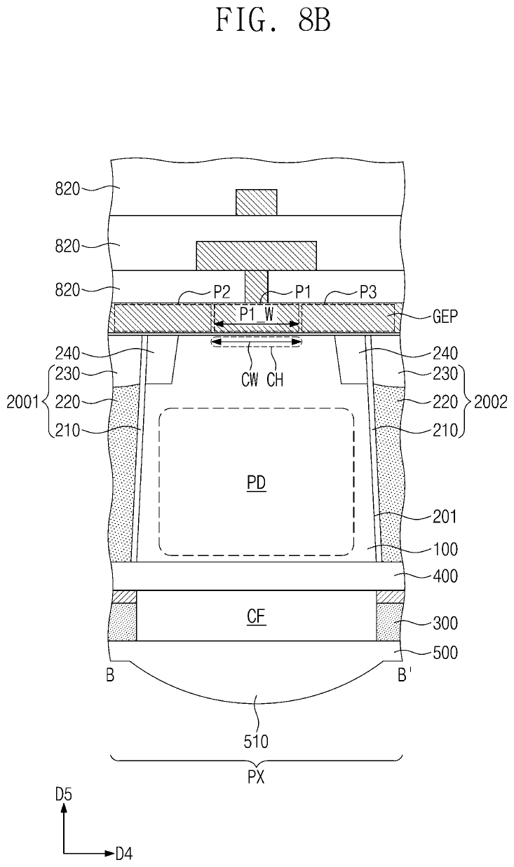

The device isolation pattern 240 may be disposed in a second trench 241, and the second trench 241 may be recessed from the second surface 100b of the first substrate 100 (e.g., in the fifth direction D5). In an embodiment, the device isolation pattern 240 may be a shallow trench isolation (STI) layer. The device isolation pattern 240 may have a depth less than that of the separation pattern 200. In an embodiment, a portion of the device isolation pattern 240 may be connected to a sidewall of a first separation pattern 210 which will be discussed with reference to FIG. 8A. In an embodiment, the device isolation pattern 240 may include, for example, one or more compounds selected from silicon oxide, silicon nitride, and silicon oxynitride.

A buried gate pattern 700 may be disposed on the second surface 100b of the first substrate 100. The buried gate pattern 700 may include the transfer gate TG of the transfer transistor Tx discussed above in FIG. 2. In an embodiment, at least one additional gate pattern may be provided on each of the pixel sections PX.

The additional gate pattern may serve as a gate electrode of at least one selected from the driver transistor Dx, the reset transistor Rx, and the selection transistor Ax that are discussed above with reference to FIG. 2. For example, the additional gate pattern may include the driver gate DG, the reset gate RG, or the selection gate AG.

The buried gate pattern 700 may have a buried type gate structure. For example, the buried gate pattern 700 may include a first part 710 and a second part 720. The first part 710 of the buried gate pattern 700 may be disposed on the second surface 100b of the first substrate 100. The second part 720 of the buried gate pattern 700 may be buried in the first substrate 100. The second part 720 of the buried gate pattern 700 may be connected to (e.g., directly connected thereto) the first part 710 of the buried gate pattern 700. However, embodiments of the present disclosure are not necessarily limited thereto. For example, in an embodiment the buried gate pattern 700 may have a planar gate structure. In this embodiment, the buried gate pattern 700 may not include the second part 720. In an embodiment, the buried gate pattern 700 may include metal, metal silicide, polysilicon, or any combination thereof. The polysilicon may include doped polysilicon.

A gate dielectric pattern 740 may be interposed between the buried gate pattern 700 and the first substrate 100. In an embodiment, the gate dielectric pattern 740 may include, for example, one or more materials selected from silicon-based dielectric materials (e.g., silicon oxide, silicon nitride, and/or silicon oxynitride) and high-k dielectric materials (e.g., hafnium oxide and/or aluminum oxide).

A first pad PAD1 may be disposed on the ground region GND. The first pad PAD1 may be disposed on and electrically connected to the ground regions GND of adjacent pixel sections PX. The first pad PAD1 on the ground regions GND may include the first node N1 discussed in FIG. 2.

A second pad PAD2 may be disposed on the floating diffusion region FD. The second pad PAD2 may be disposed on and electrically connect to the floating diffusion regions FD of adjacent pixel sections PX. The second pad PAD2 on the floating diffusion regions FD may include the second node N2 discussed in FIG. 2.

In an embodiment, the first pad PAD1 and the second pad PAD2 may include metal, metal silicide, polysilicon, or any combination thereof. For example, in an embodiment the first pad PAD1 and the second pad PAD2 may include doped polysilicon.

The first wiring layer 800 may be disposed on the second surface 100b of the first substrate 100. The first wiring layer 800 may include a first interlayer dielectric layer 810, second interlayer dielectric layers 820, and a first conductive structure 830. The first interlayer dielectric layer 810 may cover the buried gate pattern 700 and the second surface 100b of the first substrate 100. The second interlayer dielectric layers 820 may be stacked on the first interlayer dielectric layer 810. In an embodiment, the first and second interlayer dielectric layers 810 and 820 may include a silicon-based dielectric material, for example, silicon oxide, silicon nitride, and/or silicon oxynitride.

The first conductive structure 830 may be disposed in the first and second interlayer dielectric layers 810 and 820. The first conductive structure 830 may include contacts, wiring lines, and vias. The contact may be disposed in the first interlayer dielectric layer 810 and connected to at least one selected from the buried gate pattern 700, the first pad PAD1, the second pad PAD2, and the impurity regions 111. The wiring line of the first conductive structure 830 may be connected to the contact of the first conductive structure 830. The via of the first conductive structure 830 may penetrate at least one of the second interlayer dielectric layers 820 and connect to each other the wiring lines that are vertically adjacent to each other. The first conductive structure 830 may receive photoelectric signals that are output from the photoelectric conversion regions PD.

The following will describe a circuit chip 20 of the image sensor and will also describe the optical black zone OBR and the pad zone PDR of the first substrate 100. Referring back to FIGS. 3 and 4, the optical black zone OBR of the first substrate 100 may be interposed between the pixel array zone APS and the pad zone PDR. The optical black zone OB may include a first reference pixel section RPX1 and a second reference pixel section RPX2. The first reference pixel section RPX1 may be disposed between the second reference pixel section RPX2 and the pixel array zone APS. On the optical black zone OBR, the photoelectric conversion region PD may be disposed in the first reference pixel section RPX1. The photoelectric conversion region PD on the first reference pixel section RPX1 may have a planar area and a volume that is the same as those of each of the photoelectric conversion regions PD on the pixel sections PX. The photoelectric conversion region PD may not be disposed in the second reference pixel section RPX2. The impurity regions 111, the buried gate pattern 700, and the device isolation pattern 240 may be disposed on each of the first and second reference pixel sections RPX1 and RPX2.

In an embodiment, the dielectric layer 400 may extend from the pixel array zone APS through the optical black zone OBR onto the pad zone PDR. A light-shield layer 950 may be provided on the optical black zone OBR. The light-shield layer 950 may be disposed on a top surface of the dielectric layer 400. The light-shield layer 950 may prevent light from entering the photoelectric conversion region PD on the optical black zone OBR. On the optical black zone OBR, pixels of the first and second reference pixel sections RPX1 and RPX2 may output noise signals without outputting photoelectric signals. The noise signals may be generated from electrons produced due to heat or dark current. The light-shield layer 950 may not cover the pixel array zone APS, and thus light may be incident on the photoelectric conversion regions PD on the pixel array zone APS. The noise signals may be removed from photoelectric signals that are output from the pixel sections PX. In an embodiment, the light-shield layer 950 may include metal, such as tungsten, copper, aluminum, or any alloy thereof.

On the optical black zone OBR of the first substrate 100, a first conductive pattern 911 may be disposed between the dielectric layer 400 and the light-shield layer 950 (e.g., in the fifth direction D5). The first conductive pattern 911 may serve as a barrier layer or an adhesive layer. In an embodiment, the first conductive pattern 911 may include one or more of metal and metal nitride. For example, the first conductive pattern 911 may include metal, such as copper, tungsten, aluminum, titanium, tantalum, or any alloy thereof. The first conductive pattern 911 may not extend onto the pixel array zone APS of the first substrate 100.

On the optical black zone OBR of the first substrate 100, a contact plug 960 may be disposed on the first surface 100a of the first substrate 100. The contact plug 960 may be disposed on an outermost separation pattern 200 in the optical black zone OBR. The first surface 100a of the first substrate 100 may include a contact trench that penetrates the dielectric layer 400, and the contact plug 960 may be disposed in the contact trench.

The contact plug 960 may include a different material from that of the light-shield layer 950. For example, in an embodiment the contact plug 960 may include a metallic material, such as aluminum. The first conductive pattern 911 may extend between the contact plug 960 and the dielectric layer 400 and between the contact plug 960 and the separation pattern 200.

A protective dielectric layer 471 may be provided on the optical black zone OBR. The protective dielectric layer 471 may be disposed on a top surface of the light-shield layer 950 and a top surface of the contact plug 960. In an embodiment, the protective dielectric layer 471 may include the same material as that of the protective layer 470 and may be connected to (e.g., directly connected to) the protective layer 470. For example, in an embodiment the protective dielectric layer 471 may be integrally formed with the protective layer 470. However, embodiments of the present disclosure are not necessarily limited thereto. For example, in an embodiment the protective dielectric layer 471 may be formed by a process separate from that used for forming the protective layer 470, and may be spaced apart from the protective layer 470. In an embodiment, the protective dielectric layer 471 may include a high-k dielectric material, such as aluminum oxide and/or hafnium oxide.

A filtering layer 550 may further be disposed on the first surface 100a on the optical black zone OBR. The filtering layer 550 may cover a top surface of the protective dielectric layer 471. In an embodiment, the filtering layer 550 may block light having wavelengths that are different from that of light produced from the color filters CF. For example, in an embodiment the filtering layer 550 may block an infrared ray. The filtering layer 550 may include a blue color filter. However, embodiments of the present disclosure are not necessarily limited thereto.

An organic layer 501 may be provided on a top surface of the filtering layer 550. The organic layer 501 may be transparent. A top surface of the organic layer 501 may be substantially flat. For example, the organic layer 501 may include a polymer. The organic layer 501 may have dielectric characteristics. According to an embodiment of the present inventive concepts, differently from that shown, the organic layer 501 may be connected to the microlens layer 500. The organic layer 501 may include the same material as that of the microlens layer 500.

A coating layer 531 may be disposed on (e.g., disposed directly thereon) the organic layer 501. The coating layer 531 may conformally cover the top surface of the organic layer 501. The coating layer 531 may include a dielectric material and may be transparent. In an embodiment, the coating layer 531 may include the same material as that of the lens coating layer 530.

The image sensor may further include the circuit chip 20. The circuit chip 20 may be stacked on the sensor chip 10 (e.g., in the fifth direction D5). The circuit chip 20 may include a second wiring layer 1800 and a second substrate 1000. The second wiring layer 1800 may be interposed between the first wiring layer 800 and the second substrate 1000 (e.g., in the fifth direction D5). Integrated circuits 1700 may be disposed on a top surface of the second substrate 1000 or in the second substrate 1000. In an embodiment, the integrated circuits 1700 may include logic circuits, memory circuits, or a combination thereof. The integrated circuits 1700 may include, for example, transistors.

The second wiring layer 1800 may include third interlayer dielectric layers 1820 and second conductive structures 1830. The second conductive structures 1830 may be disposed between or in the third interlayer dielectric layers 1820. The second conductive structures 1830 may be electrically connected to the integrated circuits 1700. The second conductive structures 1830 may further include via patterns, and the via patterns and the second conductive structures 1830 may be coupled to each other in the third interlayer dielectric layers 1820.

An external bonding pad 600 may be disposed on the pad zone PDR of the first substrate 100. The external bonding pad 600 may be positioned adjacent to the first surface 100a of the first substrate 100. In an embodiment, the external bonding pad 600 may be buried in the first substrate 100. For example, a pad trench 990 may be defined on the first surface 100a of the first substrate 100 on the pad zone PDR, and the external bonding pad 600 may be disposed in the pad trench 990. In an embodiment, the external bonding pad 600 may include metal, such as aluminum, copper, tungsten, titanium, tantalum, or any alloy thereof. In a mounting process of the image sensor, a bonding wire may be formed on and coupled to the external bonding pad 600. The external bonding pad 600 may be electrically connected through the bonding wire to an external apparatus.

A first through hole 901 may be defined adjacent to a first side of the external bonding pad 600. The first through hole 901 may be disposed between the external bonding pad 600 and the contact plug 960. The first through hole 901 may penetrate the dielectric layer 400, the first substrate 100, and the first wiring layer 800. The first through hole 901 may further penetrate at least a portion of the second wiring layer 1800. The first through hole 901 may have a first bottom surface and a second bottom surface. The first bottom surface of the first through hole 901 may expose the first conductive structure 830. The second bottom surface of the first through hole 901 may be located at a lower level than that of the first bottom surface of the first through hole 901. The second bottom surface of the first through hole 901 may expose the second conductive structure 1830.

The first conductive pattern 911 may extend from the optical black zone OBR onto the pad zone PDR. The first conductive pattern 911 may cover an inner wall of the first through hole 901. The first conductive pattern 911 in the first through hole 901 may be in direct contact with a top surface of the first conductive structure 830. Therefore, the first conductive structure 830 may be electrically connected through the first conductive pattern 911 to a second separation pattern 220 which will be discussed below with reference to FIG. 8A.

The first conductive pattern 911 in the first through hole 901 may also be in direct contact with a top surface of the second conductive structure 1830. The second conductive structure 1830 may be electrically connected through the first conductive pattern 911 to the first conductive structure 830 and the second separation pattern 220.

A first buried pattern 921 may be disposed in the first through hole 901, thereby filling the first through hole 901. In an embodiment, the first buried pattern 921 may include a low-refractive material and may have dielectric characteristics. The first buried pattern 921 may include the same material as that of the first fence pattern 310. The first buried pattern 921 may have a recess on a top surface thereof. For example, the top surface of the first buried pattern 921 may be lower than an edge (e.g., a lateral edge) of the top surface of the first buried pattern 921.

A first capping pattern 931 may be disposed on the top surface of the first buried pattern 921, thereby filling the recess of the first buried pattern 921. A top surface of the first capping pattern 931 may be substantially flat. In an embodiment, the first capping pattern 931 may include a dielectric polymer, such as a photoresist material.

A second through hole 902 may be defined adjacent to a second side of the external bonding pad 600. The second through hole 902 may penetrate the dielectric layer 400, the first substrate 100, and the first wiring layer 800. The second through hole 902 may penetrate a portion of the second wiring layer 1800 and may expose the second conductive structure 1830.

A second conductive pattern 912 may be disposed on the pad zone PDR. The second conductive pattern 912 may be disposed in the second through hole 902 to conformally cover a sidewall and a bottom surface of the second through hole 902. The second conductive pattern 912 may be electrically connected to the second conductive structure 1830.

The second conductive pattern 912 may be interposed between the external bonding pad 600 and the pad trench 990 to cover a bottom surface and a sidewall (e.g., lateral sidewalls) of the external bonding pad 600. When the image sensor operates, the integrated circuits 1700 of the circuit chip 20 may transceive electrical signals through the second conductive structure 1830, the second conductive pattern 912, and the external bonding pad 600.

A second buried pattern 922 may be disposed in the second through hole 902, thereby filling the second through hole 902. The second buried pattern 922 may include a low-refractive material and may have dielectric characteristics. For example, in an embodiment the second buried pattern 922 may include the same material as that of the first fence pattern 310. The second buried pattern 922 may have a recess on a top surface thereof.

A second capping pattern 932 may be disposed on the top surface of the second buried pattern 922, thereby filling the recess of the second buried pattern 922. A top surface of the second capping pattern 932 may be substantially flat. The second capping pattern 932 may include a dielectric polymer, such as a photoresist material.

The protective dielectric layer 471 may extend from the optical black zone OBR onto the pad zone PDR. The protective dielectric layer 471 may be disposed on the top surface of the dielectric layer 400, and may extend into the first through hole 901 and the second through hole 902. In the first through hole 901, the protective dielectric layer 471 may be interposed between the first conductive pattern 911 and the first buried pattern 921. In the second through hole 902, the protective dielectric layer 471 may be interposed between the second conductive pattern 912 and the second buried pattern 922. The protective dielectric layer 471 may expose the external bonding pad 600.

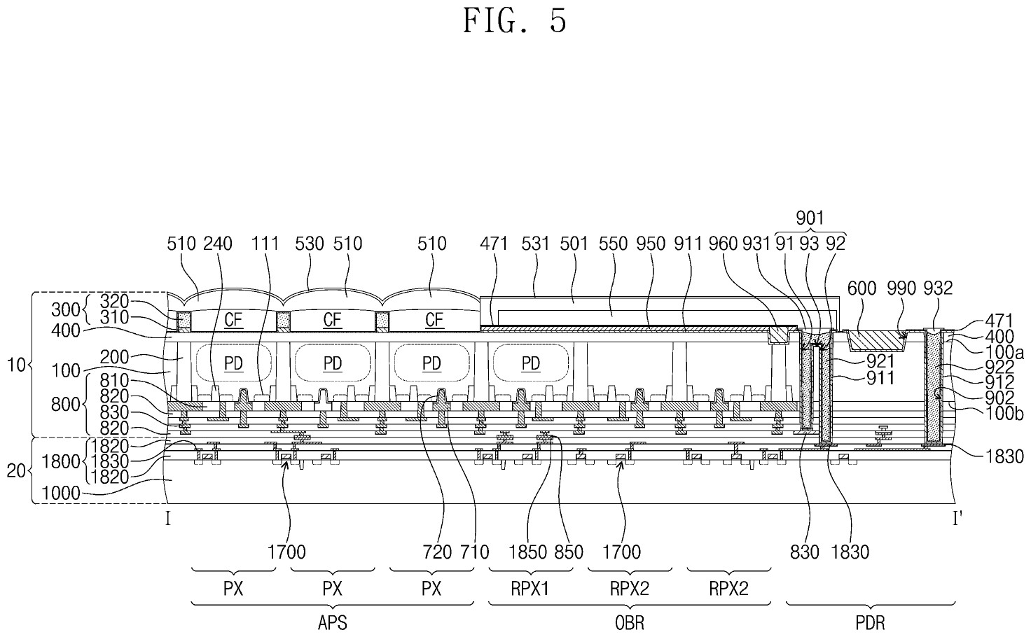

FIG. 5 illustrates a cross-sectional view taken along line I-I′ of FIG. 3, showing an image sensor according to some embodiments of the present inventive concepts. In the embodiment that follows, a detailed description of technical features repetitive to those discussed with reference to FIGS. 2 to 4 may be omitted, and differences thereof will be discussed in detail.

Referring to FIGS. 3 and 5, an image sensor may include a sensor chip 10 and a circuit chip 20. The sensor chip 10 may include a first connection pad 850. The first connection pad 850 may be exposed on a bottom surface of the sensor chip 10. The first connection pad 850 may be disposed in a lowermost second interlayer dielectric layer 820. The first connection pad 850 may be electrically connected to the first conductive structure 830. In an embodiment, the first connection pad 850 may include a conductive material, such as metal. For example, the first connection pad 850 may include copper. Alternatively, the first connection pad 850 may include one or more compounds selected from aluminum, tungsten, titanium, or any alloy thereof

The circuit chip 20 may include a second connection pad 1850. The second connection pad 1850 may be exposed on a top surface of the circuit chip 20. The second connection pad 1850 may be disposed in an uppermost third interlayer dielectric layer 1820. The second connection pad 1850 may be electrically connected to the integrated circuit 1700. The second connection pad 1850 may include a conductive material, such as metal. For example, in an embodiment the second connection pad 1850 may include copper. Alternatively, the second connection pad 1850 may include one or more compounds selected from aluminum, tungsten, titanium, or any alloy thereof

In an embodiment, the circuit chip 20 and the sensor chip 10 may be connected to each other by direct bonding. For example, the first connection pad 850 and the second connection pad 1850 may be vertically aligned and in direct contact with each other. Therefore, the second connection pad 1850 may be directly bonded to the first connection pad 850. As a result, the integrated circuits 1700 of the circuit chip 20 may be electrically connected through the first and second connection pads 850 and 1850 to the external bonding pads 600 or transistors of the sensor chip 10.

The second interlayer dielectric layer 820 may be directly attached to the third interlayer dielectric layer 1820. In this embodiment, a chemical bond may be formed between the second interlayer dielectric layer 820 and the third interlayer dielectric layer 1820.

In an embodiment as shown in FIG. 5, the first through hole 901 may include a first through hole part 91, a second through hole part 92, and a third through hole part 93. The first through hole part 91 may penetrate the dielectric layer 400, the first substrate 100, and the first wiring layer 800, and may have a first bottom surface. The second through hole part 92 may penetrate the dielectric layer 400, the first substrate 100, and the first wiring layer 800, and may extend into an upper portion of the second wiring layer 1800. The second through hole part 92 may have a second bottom surface, and the second bottom surface may expose the top surface of the second conductive structure 1830. The second through hole part 92 may have a sidewall spaced apart from that of the first through hole part 91. The third through hole part 93 may be disposed between and connected to an upper portion of the first through hole part 91 and an upper portion of the second through hole part 92. The first through hole 901 may be disposed therein with the first conductive pattern 911, the protective dielectric layer 471, and the first buried pattern 921. The first conductive pattern 911 may cover inner walls of the first, second, and third through hole parts 91, 92, and 93.

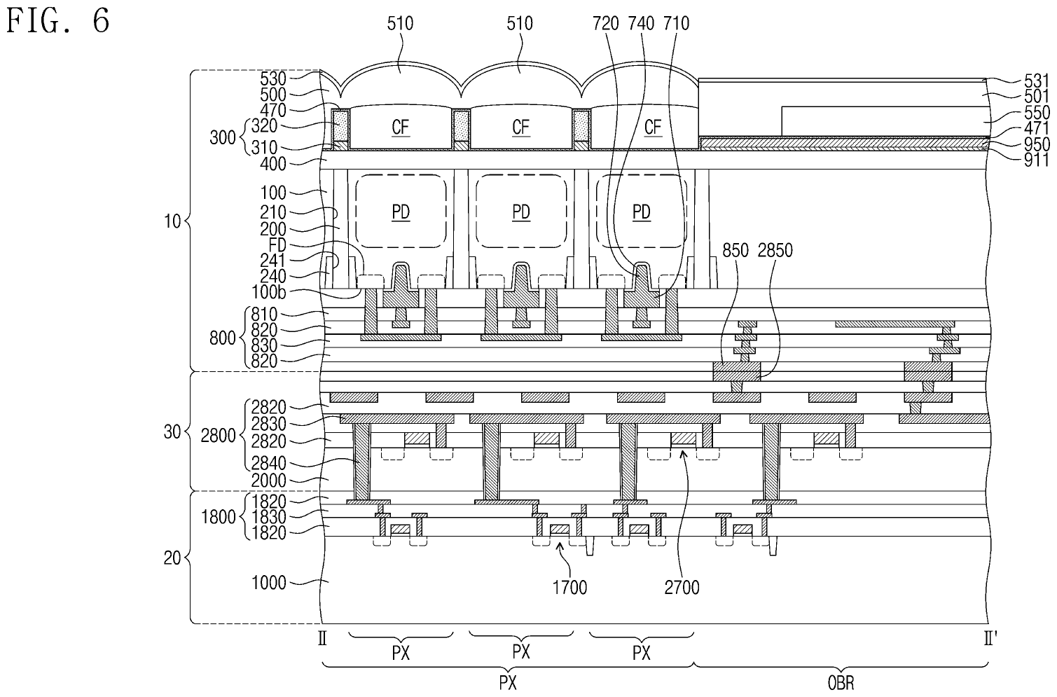

FIG. 6 illustrates a cross-sectional view taken along line II-II′ of FIG. 3, showing an image sensor according to some embodiments of the present inventive concepts. In the embodiment that follows, a detailed description of technical features repetitive to those discussed with reference to FIGS. 2 to 5 may be omitted, and differences thereof will be discussed in detail.

Referring to FIGS. 3 and 6, an image sensor may further include a middle chip 30 interposed between the sensor chip 10 and the circuit chip 20. The middle chip 30 may include a third wiring layer 2800 and a third substrate 2000. The third wiring layer 2800 may be interposed between the first wiring layer 800 and the third substrate 2000. The second wiring layer 1800 of the circuit chip 20 may be disposed below the third substrate 2000.

The third substrate 2000 may include driver transistors 2700 on a top surface thereof. In an embodiment, the driver transistors 2700 may include the reset transistor Rx, the driver transistor Dx, and/or the selection transistor Ax that are discussed with reference to FIG. 2. Additionally or alternatively, the driver transistors 2700 may include a conversion gain transistor. According to an embodiment, the photoelectric conversion region PD, the transfer transistor Tx, and the floating diffusion region FD of FIG. 2 may be disposed in or on the first substrate 100 of the sensor chip 10. The middle chip 30 may be disposed on the third substrate 2000 with the reset transistor Rx, the driver transistor Dx, and the selection transistor Ax of FIG. 2.

The third wiring layer 2800 may include fourth interlayer dielectric layers 2820 and third conductive structures 2830. The third conductive structures 2830 may be disposed between or in the fourth interlayer dielectric layers 2820. The third conductive structures 2830 may be electrically connected to the driver transistors 2700. In an embodiment, the third conductive structures 2830 may include contacts, wiring lines, and vias.

The sensor chip 10 may include a first connection pad 850. The first connection pad 850 may be exposed on a bottom surface of the sensor chip 10. The first connection pad 850 may be disposed in a lowermost second interlayer dielectric layer 820. The first connection pad 850 may be electrically connected to the first conductive structure 830.

The middle chip 30 may include a third connection pad 2850. The third connection pad 2850 may be exposed on a top surface of the middle chip 30. The third connection pad 2850 may be disposed in an uppermost fourth interlayer dielectric layer 2820. The third connection pad 2850 may be electrically connected to the driver transistors 2700. The third connection pad 2850 may include a conductive material, such as metal. For example, in an embodiment the third connection pad 2850 may include copper. Alternatively, the third connection pad 2850 may include one or more compounds selected from aluminum, tungsten, titanium, or any alloy thereof

In an embodiment, the middle chip 30 and the sensor chip 10 may be connected to each other by direct bonding. For example, the first connection pad 850 and the third connection pad 2850 may be vertically aligned and in direct contact with each other. Therefore, the third connection pad 2850 may be directly bonded to the first connection pad 850. As a result, the driver transistors 2700 of the middle chip 30 may be electrically connected through the first and third connection pads 850 and 2850 to the floating diffusion regions FD of the sensor chip 10.

The second interlayer dielectric layer 820 may be directly attached to the fourth interlayer dielectric layer 2820. In this embodiment, a chemical bond may be formed between the second interlayer dielectric layer 820 and the fourth interlayer dielectric layer 2820.

The middle chip 30 may further include through vias 2840 that penetrate the third substrate 2000. Each of the through vias 2840 may electrically connect the third wiring layer 2800 to the second wiring layer 1800. For example, the middle chip 30 and the circuit chip 20 may be electrically connected to each other through the through vias 2840.

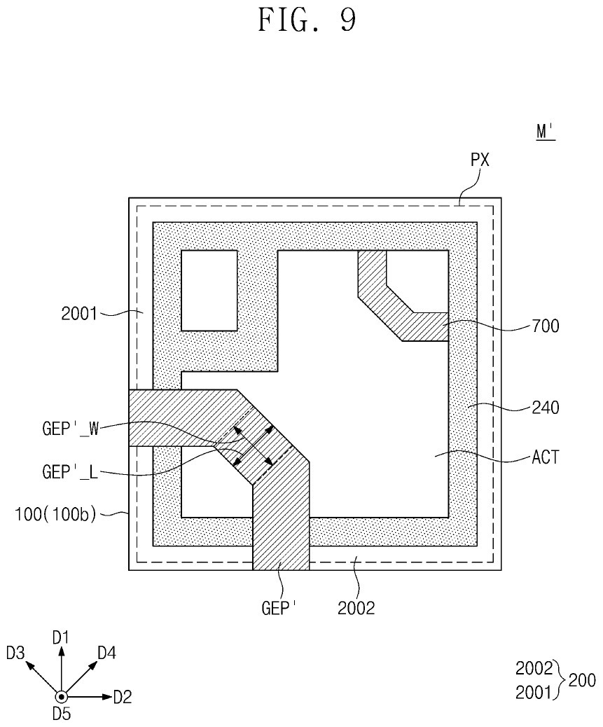

FIG. 7 illustrates an enlarged plan view of section M depicted in FIG. 3, showing a pixel of an image sensor according to some embodiments of the present inventive concepts. FIG. 8A illustrates a cross-sectional view taken along line A-A′ of FIG. 7. FIG. 8B illustrates a cross-sectional view taken along line B-B′ of FIG. 7. FIG. 9 illustrates a plan view of section M depicted in FIG. 3, showing a pixel different from that of an image sensor according to some embodiments of the present inventive concepts. In an embodiment that follows, a detailed description of technical features repetitive to those discussed above with reference to FIGS. 2 to 6 may be omitted, and differences thereof will be explained in detail.

Referring to FIGS. 7, 8A, and 9, an image sensor according to some embodiments of the present inventive concepts may include at least one pixel section PX. The pixel section PX may be a region for one of pixels of the active pixel sensor array 1 depicted in FIG. 1.

The first substrate 100 may have a first surface (e.g., a rear surface) 100a and a second surface (e.g., a front surface) 100b. The pixel section PX may be defined by a separation pattern 200 that penetrates the first substrate 100. The separation pattern 200 may include a first sub-separation pattern 2001 and a second sub-separation pattern 2002. The first sub-separation pattern 2001 may extend in the first direction D1. The second sub-separation pattern 2002 may extend in the second direction D2 that intersects the first direction D1. The first and second directions D1, D2 may both be parallel to an upper surface of the first substrate 100. For example, when viewed in a plan view, the separation pattern 200 may have a rectangular annular shape that surrounds the pixel section PX.

Referring back to FIGS. 8A and 8B, the separation pattern 200 may include a first separation pattern 210, a second separation pattern 220, and a dielectric pattern 230. Each of the first sub-separation pattern 2001 and the second sub-separation pattern 2002 may include the first separation pattern 210, the second separation pattern 220, and the dielectric pattern 230.

The first separation pattern 210 may be disposed on a sidewall of the first trench 201. In an embodiment, the first separation pattern 210 may include, for example, one or more materials selected from silicon-based dielectric materials (e.g., silicon nitride, silicon oxide, and/or silicon oxynitride) and high-k dielectric materials (e.g., hafnium oxide and/or aluminum oxide). Alternatively, the first separation pattern 210 may include a plurality of layers. In an embodiment, the plurality of layers may include different materials from each other. The first separation pattern 210 may have a refractive index less than that of the first substrate 100. Accordingly, crosstalk issues may be prevented or reduced between the pixel sections PX of the first substrate 100.

The second separation pattern 220 may be disposed in the first separation pattern 210. For example, the first separation pattern 210 may be interposed between the second separation pattern 220 and the first substrate 100. The first separation pattern 210 may separate the second separation pattern 220 from the first substrate 100. Therefore, when the image sensor operates, the second separation pattern 220 may be electrically separated from the first substrate 100. In an embodiment, the second separation pattern 220 may include a conductive material, for example, doped polysilicon. The second separation pattern 220 may include impurities having the first conductivity type or the second conductivity type.

The dielectric pattern 230 may be disposed on the second separation pattern 220 (e.g., in the fifth direction D5). A top surface of the dielectric pattern 230 may be coplanar (e.g., in the fifth direction D5) with the second surface 100b of the first substrate 100. In an embodiment, the dielectric pattern 230 may include a silicon-based dielectric material, for example, silicon oxide.

The contact plug 960 discussed in FIG. 4 may be electrically connected through the first conductive pattern 911 to the second separation pattern 220. In an embodiment, a negative bias voltage may be applied through the contact plug 960 to the second separation pattern 220. Positive charges generated from the pixel section PX may be eliminated through the second separation pattern 220 that surrounds the pixel section PX. Therefore, the image sensor may provide increased dark current characteristics.

A photoelectric conversion region PD may be disposed in the pixel section PX. The photoelectric conversion region PD may include a first region adjacent to the first surface 100a and a second region adjacent to the second surface 100b. In an embodiment, there may be a difference in concentration between the first region and the second region of the photoelectric conversion region PD. Therefore, the photoelectric conversion region PD may have a potential slope between the first surface 100a and the second surface 100b of the first substrate 100.

The first substrate 100 and the photoelectric conversion region PD may constitute a photodiode. For example, the photodiode may be constituted by a p-n junction between the first substrate 100 of the first conductivity type and the photoelectric conversion region 110 of the second conductivity type. The photoelectric conversion regions PD that constitute the photodiode may generate and accumulate photo-charges in proportion to intensity of incident light.

A device isolation pattern 240 may be disposed on the second surface 100b of the first substrate 100. The device isolation pattern 240 may define a ground region GND, a floating diffusion region FD, and an active region ACT in the pixel section PX. The active region ACT may include impurity regions (see 111 of FIG. 4).

The active region ACR may include a first impurity region 111_D and a second impurity region 111_S. The first impurity region 111_D and the second impurity region 111_S may be arranged to be spaced apart from each other along the fourth direction D4. For example, as shown in the plan view of FIG. 7, the active region ACT may have a shape that expands in the fourth direction D4. The first impurity region 111_D may be a drain region. The second impurity region 111_S may be a source region. The first impurity region 111_D may have an area less than that of the second impurity region 111_S. In an embodiment, a concentration of impurities in the vicinity of an interface between the source region and the active region ACT and between the drain region and the active region ACT may be about 20% to about 30% of a maximum concentration of impurities in the active region ACT.

The first impurity region 111_D may have a triangular shape when viewed in a plan view. The second impurity region 111_S may include a central portion CP, a first edge region E1 that extends in the first direction D1 from the central portion CP, and a second edge region E2 that extends in the second direction D2 from the central portion CP. The second impurity region 111_S may have a dumbbell shape whose one lateral surface is flat. The planar shape of each of the first and second impurity regions 111_D and 111_S is not limited thereto and may be variously changed.

A first active contact AC_SD1 may be disposed on the first impurity region 111_D, and may electrically connect the first impurity region 111_D to a first wiring line 831. At least one first active contact AC_SD1 may be disposed on the first impurity region 111_D.

A second active contact AC_SD2 may be disposed on the second impurity region 111_S, and may electrically connect the second impurity region 111_S to a first wiring line 831. In an embodiment, a plurality of second active contacts AC_SD2 may be disposed on the second impurity region 111_S. The second active contact AC_SD2 may be disposed on the first edge region E1 or the second edge region E2. The second active contact AC_SD2 may be disposed on the central portion CP.

In an embodiment, the number of first active contacts AC_SD1 provided on the first impurity region 111_D may be less than that of second active contacts AC_SD2 provided on the second impurity region 111_S. When viewed in a plan view, an area of the first active contact AC_SD1 provided on the first impurity region 111_D may be less than that of the second active contact AC_SD2 provided on the second impurity region 111_S.

In an embodiment, the device isolation pattern 240 may separate the ground region GND from the floating diffusion region FD and the active region ACT. For example, in an embodiment the ground region GND may have an island shape surrounded by the device isolation pattern 240.

At least one gate pattern GEP may be disposed on the active region ACT. One transistor may be constituted by the first impurity region 111_D, the second impurity region 111_S, and the gate pattern GEP. For example, in an embodiment the first impurity region 111_D, the second impurity region 111_S, and the gate pattern GEP may constitute at least one selected from the driver transistor Dx, the reset transistor Rx, and the selection transistor Ax that are discussed with reference to FIG. 2. The gate pattern GEP may extend parallel to the second surface 100b of the first substrate 100, and may be disposed between the first impurity region 111_D and the second impurity region 111_S. The second surface 100b may correspond to a top surface of the first substrate 100.

In an embodiment, the gate pattern GEP may be a driver gate pattern and may be disposed on the active region ACT of the pixel section PX1. The active region ACT and the gate pattern GEP of the pixel section PX may constitute the driver transistor Dx discussed with reference to FIG. 2. For example, the driver transistor Dx may be a source follower transistor.

The gate pattern GEP may extend along the third direction D3 from the first sub-separation pattern 2001 through the active region ACT and the device isolation pattern 240 to the second sub-separation pattern 2002. The gate pattern GEP may have a first surface S1 and a second surface S2 that are opposite to each other. The first surface S1 may be close to the first impurity region 111_D, and the second surface S2 may be close to the second impurity region 111_S. In an embodiment, the gate pattern GEP may include a conductive material, such as a doped polysilicon. However, embodiments of the present disclosure are not necessarily limited thereto.

In an embodiment, the gate pattern GEP may be disposed between the first impurity region 111_D and the second impurity region 111_S, and the first surface S1 close to the first impurity region 111_D may extend linearly on the active region ACT. For example, a linear portion of the first surface S1 disposed on the active region ACT may be in a range of about 95% to about 100% of the first surface S1.

The first surface S1 of the gate pattern GEP may extend linearly from the first sub-separation pattern 2001 to the second sub-separation pattern 2002 (e.g., in the third direction D3). The first surface S1 may be flat. The second surface S2 of the gate pattern GEP may include a first sub-surface SS1, a second sub-surface SS2, and a third sub-surface SS3. The first sub-surface SS1 may be disposed between the second sub-surface SS2 and the third sub-surface SS3. The second surface S2 may include a first corner CN1 where the first sub-surface SS1 and the second sub-surface SS2 meet each other and a second corner CN2 where the first sub-surface SS1 and the third sub-surface SS3 meet each other.

The first sub-surface SS1 may extend along the third direction D3. The first sub-surface SS1 and the first surface S1 may be parallel to each other. The second sub-surface SS2 may extend along the second direction D2. The third sub-surface SS3 may extend along the first direction D1.

The first sub-surface SS1, the second sub-surface SS2, and the third sub-surface SS3 may be connected to each other to constitute the second surface S2. The second surface S3 may include a first corner where the first sub-surface SS1 and the second sub-surface SS2 meet each other and a second corner where the third sub-surface SS1 and the third sub-surface SS3 meet each other. The second surface S2 may extend from the first sub-separation pattern 2001 to the second sub-separation pattern 2002.

In an embodiment, the gate pattern GEP may include a first portion P1, a second portion P2, and a third portion P3 that are arranged along the third direction D3. The second portion P2 may extend from the first sub-separation pattern 2001 through the device isolation pattern 240 to the active region ACT. The third portion P3 may extend from the second sub-separation pattern 2002 through the device isolation pattern 240 to the active region ACT. The first portion P1 may be interposed between the second portion P2 and the third portion P3 (e.g., in the third direction D3). One side of the first portion P1 may be adjacent to the second portion P2, and another side of the first portion P1 may be adjacent to the third portion P3.

A length of the first portion P1 in the third direction D3 may be a first distance P1_W. When viewed in a plan view, the first length P1_W may be a horizontal length of the first portion P1. A length of the first portion P1 in the fourth direction D4 may be a second distance P1_L. When viewed in a plan view, the second distance P1_L may be a vertical length in the first portion P1. In an embodiment, the first distance P1_W may be greater than the second distance P1_L.

Referring back to FIGS. 8A and 8B, a driver transistor (e.g., Dx of FIG. 2) may be constituted by the first impurity region 111_D, the second impurity region 111_S, and the gate pattern GEP of the active region ACT of the pixel section PX. The driver transistor may include a channel CH that is disposed below the gate pattern GEP and between the first impurity region 111_D and the second impurity region 111_S (e.g., in the fourth direction D4). The channel CH may have an effective channel length CL and an effective channel width CW. The effective channel length CL may be measured in the fourth direction D4. The effective channel width CW may be measured in the third direction D3.

In an embodiment, the effective channel length CL may be the same as the second distance P1_L of the first portion P1 of the gate pattern GEP. The effective channel width CW may be the same as the first distance P1_W of the first portion P1 of the gate pattern GEP. An increase in the effective channel width CW may cause an increase in charge that flows when the driver transistor is turned on, and thus the driver transistor may have increased electrical properties.

Referring to FIG. 9, a portion of a gate pattern GEP′ may have a third distance GEP′_W in the third direction D3 and a fourth distance GEP′_L I in the fourth direction D4. A driver transistor including the gate pattern GEP′ may have an effective channel width that is the same as the third distance GEP′_W. A driver transistor including the gate pattern GEP′ may have an effective channel length that is the same as the fourth distance GEP′_L.

When the gate pattern GEP of FIG. 7 according to an embodiment of the present inventive concepts is compared with the gate pattern GEP′ of FIG. 9, the second distance P1_L may be substantially the same as the fourth distance GEP′_L. For example, the driver transistors of FIGS. 7 and 9 may have their effective channel lengths that are substantially the same as each other. The first distance P1_W may be greater than the third distance GEP′_W. Therefore, the driver transistor of an embodiment shown in FIG. 7 may have an effective channel width greater than that of the driver transistor of a comparative embodiment shown in FIG. 9. For example, the driver transistor depicted in FIG. 7 according to some embodiments of the present inventive concepts may have a greater effective channel width compared to an effective channel length than an effective channel width compared to an effective channel length of the driver transistor depicted in FIG. 9. Accordingly, image sensors according to some embodiments of the present inventive concepts may provide increased performance.

For example, the gate pattern GEP of the driver transistor (see Dx of FIG. 2) may be formed as shown in FIG. 7, it may be possible to avoid the occurrence of noise in an image sensor. During the formation of an image sensor, excess charges may be created due to defects occurring in an etching process for forming the device isolation pattern 240 in the pixel sections PX, and the excess charges may become a cause of dark current irrespective of light incident on photodiodes. A magnitude of dark current may be affected by an area of the device isolation pattern 240. For example, an increase in area of the device isolation pattern 2540 may induce an increase in dark current.

In addition, thermal noise may be generated during operation of an image sensor, and flicker noise may be created due to charges that flow along a channel of a driver transistor and trapped at an interface between the first substrate 100 and the device isolation pattern 240. The thermal noise generated during the operation of an image sensor may be in inverse proportion to a channel width compared to a channel length of the driver transistor, and the flicker noise may be in inverse proportion to a product of the channel length and the channel width.

According to an embodiment of the present inventive concepts, the first surface S1 of the gate pattern GEP of a driver transistor may extend linearly. Therefore, there may be a relatively small region where the device isolation pattern 240 is adjacent to a channel of a transistor, and the transistor may have a wider channel width compared to a channel length than a channel width compared to the same channel length of a comparative image sensor. For example, a region of the device isolation pattern 240 adjacent to a channel may be reduced to decrease noise caused by dark current. In addition, an effective channel width compared to an effective channel length and a product of the effective channel length and the effective channel width of a driver transistor may be increased to reduce thermal noise and flicker noise. Therefore, a random noise phenomenon may be reduced to increase performance of an image sensor.

A buried gate pattern 700 may be disposed between the active region ACT and the floating diffusion region FD. Spacers SPA may be disposed on opposite sidewalls of the buried gate pattern 700. In an embodiment, the spacers SPA may include a silicon-based dielectric material, such as one or more compounds selected from silicon oxide, silicon nitride, and silicon oxynitride. However, embodiments of the present disclosure are not necessarily limited thereto.

A first wiring layer 800 may be disposed on the second surface 100b of the first substrate 100. The first wiring layer 800 may include a plurality of sequentially stacked metal layers. For example, a first metal layer may include first wiring lines 831, and a second metal layer on the first metal layer may include second wiring lines 832. A via VI may be disposed between the second wiring line 832 and the first wiring line 831. The first metal layer and the second metal layer may be connected to each other (e.g., electrically connected to each other) through the via VI. A contact may be disposed between the first wiring line 831 and each of the gate pattern GEP, the active region ACT, and the floating diffusion region FD. The first wiring line 831 may be electrically connected through the first active contact AC_SD1 to the first impurity region 111_D of the active region ACT.

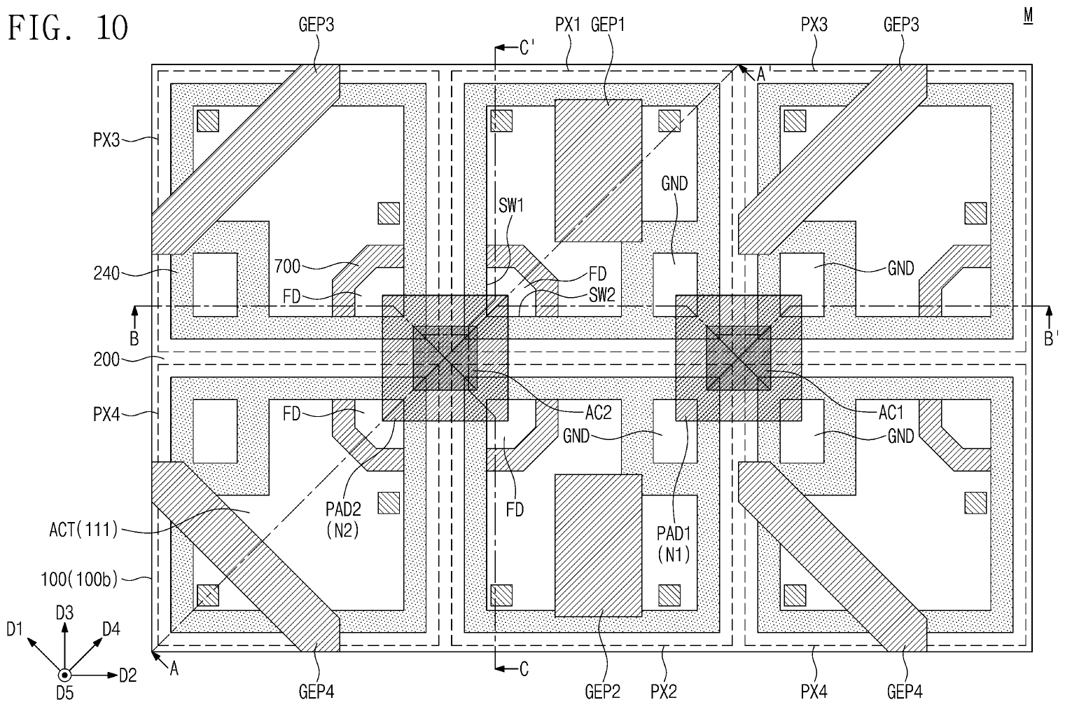

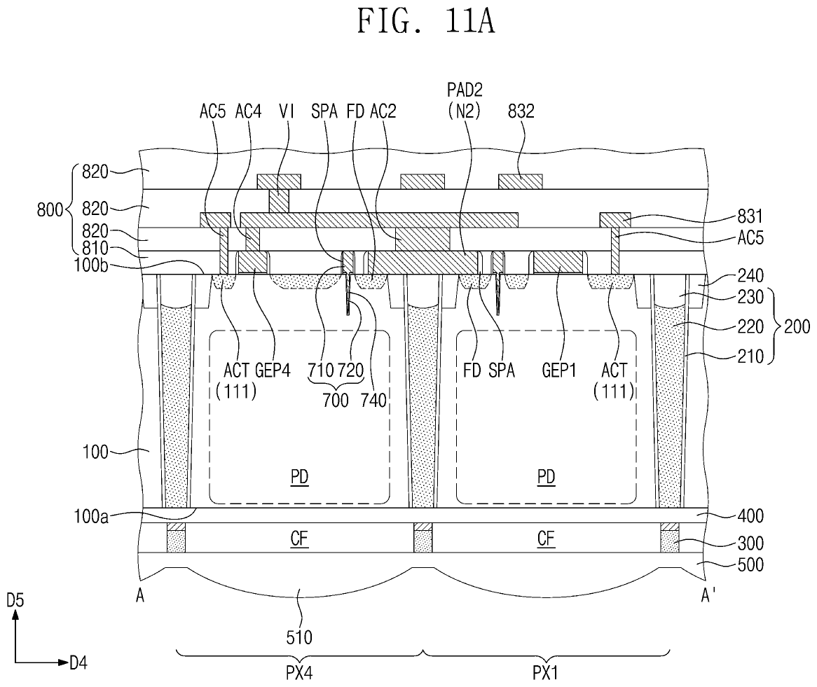

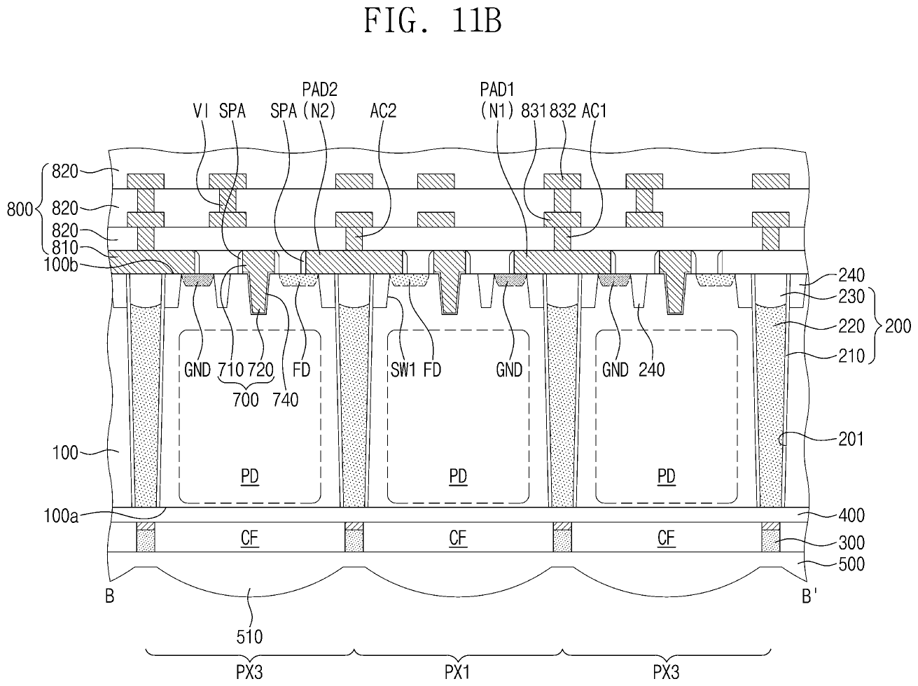

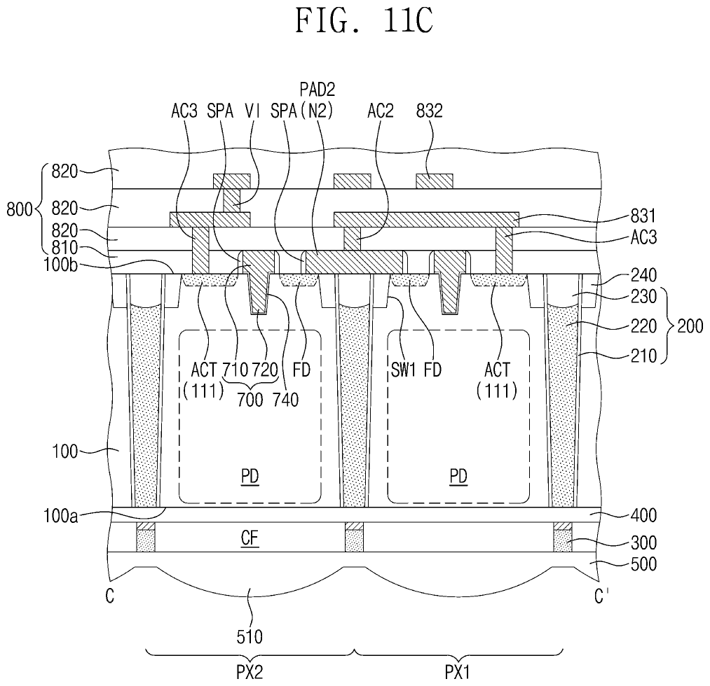

FIG. 10 illustrates a plan view of section M depicted in FIG. 3, showing a pixel of an image sensor according to some embodiments of the present inventive concepts. FIG. 11A illustrates a cross-sectional view taken along line A-A′ of FIG. 10. FIG. 11B illustrates a cross-sectional view taken along line B-B′ of FIG. 10. FIG. 11C illustrates a cross-sectional view taken along line C-C′ of FIG. 10. In an embodiment that is described herein, a detailed description of technical features repetitive to those discussed with reference to FIGS. 2 to 8B may be omitted, and differences thereof will be discussed in detail.

Referring to FIGS. 10 to 11C, an image sensor according to some embodiments of the present inventive concepts may include a plurality of pixel sections, such as first to fourth pixel sections PX1 to PX4. For example, first and second pixel sections PX1 and PX2 may be disposed adjacent to each other in the third direction D3. Third and fourth pixel sections PX3, PX4 may be disposed adjacent to each other in the third direction D3. The third pixel sections PX3 may be disposed on opposite sides of the first pixel section PX1. For example, the first pixel section PX1 may be interposed between the third pixel sections PX3 (e.g., in the second direction D2). The fourth pixel sections PX4 may be disposed on opposite sides of the second pixel section PX2. For example, the second pixel section PX2 may be interposed between the fourth pixel sections PX4 (e.g., in the second direction D2).

The separation pattern 200 and the device isolation pattern 240 may together constitute a separation structure. The separation structure may define the pixel sections PX1 to PX4, the ground regions GND, the floating diffusion regions FD, and the active regions ACT.

The active region ACT of each of the first to fourth pixel sections PX1 to PX4 may be disposed thereon with at least corresponding one of first to fourth gate patterns GEP1 to GEP4. For example, the first pixel section PX1 may include a first gate pattern GEP1, and the second pixel section PX2 may include a second gate pattern GEP2. The third pixel section PX3 may include a third gate pattern GEP3, and the fourth pixel section PX4 may include a fourth gate pattern GEP4. The active region ACT and the gate patterns GEP1 to GEP4 may constitute at least one transistor selected from the driver transistor Dx, the reset transistor Rx, and the selection transistor Ax that are discussed with reference to FIG. 2. The first to fourth gate patterns GEP1 to GEP4 may include a conductive material (e.g., doped polysilicon).

In an embodiment, each of the first and second gate patterns GEP1 and GEP2 may have a rectangular shape when viewed in a plan view. The third gate pattern GEP3 may extend along the fourth direction D4 from the separation pattern 200 through the device isolation pattern 240 and the active pattern ACT to another separation pattern 200. The fourth gate pattern GEP4 may extend along the first direction D1 from the separation pattern 200 through the device isolation pattern 240 and the active pattern ACT to another separation pattern 200. The third and fourth gate patterns GEP3 and GEP4 may have their shapes that are symmetric about the second direction D2.

A buried gate pattern 700 may be disposed between the active region ACT and the floating diffusion region FD. Spacers SPA may be disposed on opposite sidewalls of the buried gate pattern 700. In an embodiment, the spacers SPA may include a silicon-based dielectric material, such as one or more compounds selected from silicon oxide, silicon nitride, and silicon oxynitride.

In an embodiment, the floating diffusion region FD of the first pixel section PX1 may be defined by a first sidewall SW1 and a second sidewall SW2 of the device isolation pattern 240. The first sidewall SW1 may extend in the third direction D3, and the second sidewall SW2 may extend in the second direction D2.

When viewed in a plan view, referring to FIG. 10, the buried gate pattern 700 of the first pixel section PX1 may extend from the first sidewall SW1 towards the second sidewall SW2 of the device isolation pattern 240. Therefore, the floating diffusion region FD of the first pixel section PX1 may have an island shape that is surrounded by the buried gate pattern 700 and the first and second sidewalls SW1 of the device isolation pattern 240.

According to some embodiments of the present inventive concepts, an area of the floating diffusion regions FD may be reduced due to a second pad PAD2 that commonly connects the floating diffusion regions FD to each other. The reduction in area may be a result of contact-induced misalignment not needing to be considered. According to an embodiment of the present inventive concepts, the reduction in area of the floating diffusion region FD may allow the floating diffusion region FD to have an island shape that is surrounded by the device isolation pattern 240 and the buried gate pattern 700.

A first pad PAD1 may be disposed on the ground regions GND of adjacent first to fourth pixel sections PX1 to PX4. When viewed in a plan view, the first pad PAD1 may have a tetragonal shape. The first pad PAD1 may have corners that are correspondingly in direct contact with the ground regions GND of the first to fourth pixel sections PX1 to PX4. The first pad PAD1 may connect four adjacent ground regions GND to each other. For example, the first pad PAD1 connected in common to four ground regions GND may include the first node N1 of FIG. 1 through which a ground voltage VSS is applied.

The second pad PAD2 may also be disposed on the floating diffusion regions FD of adjacent first to fourth pixel sections PX1 to PX4. The second pad PAD2 may have corners that are correspondingly in direct contact with the floating diffusion regions FD of the first to fourth pixel sections PX1 to PX4. The second pad PAD2 may connect four adjacent floating diffusion regions FD to each other. The second pad PAD2 may run across the device isolation pattern 240 and the separation pattern 200 to connect adjacent floating diffusion regions FD to each other. For example, the second node N2 of FIG. 1 may be included in the second pad PAD2 that is connected in common to four floating diffusion regions FD.

One surface, such as a bottom surface, of the second pad PAD2 may be disposed on a portion of each of the first to fourth pixel sections PX1 to PX4. The one surface of the second pad PAD2 may also be disposed on a portion of the separation pattern 200 and a portion of the device isolation pattern 240.

The spacer SPA may also be disposed on a sidewall of each of the first pad PAD1 and the second pad PAD2. In an embodiment, the first pad PAD1 and the second pad PAD2 may be formed simultaneously with the buried gate pattern 700, the first gate pattern GEP1, the second gate pattern GEP2, the third gate pattern GEP3, and the fourth gate pattern GEP4. Therefore, the first and second pads PAD1 and PAD2 may include the same conductive material (e.g., doped poly-silicon) of that of the buried gate pattern 700 and the first to fourth gate patterns GEP1 to GEP4.

A first wiring layer 800 may be disposed on the second surface 100b of the first substrate 100. The first wiring layer 800 may include a plurality of sequentially stacked metal layers. For example, a first metal layer may include first wiring lines 831, and a second metal layer on the first metal layer may include second wiring lines 832.

Referring to FIG. 11B, a first contact AC1 may be disposed between the first wiring line 831 and the first pad PAD1. In an embodiment, the first wiring line 831 may commonly apply a ground voltage VSS through the first contact AC1 and the first pad PAD1 to the ground regions GND of the first to fourth pixel sections PX1 to PX4. A second contact AC2 may be disposed between the first wiring line 831 and the second pad PAD2. The first wiring line 831 may be connected in common through the second contact AC2 and the second pad PAD2 to the floating diffusion regions FD of the first to fourth pixel sections PX1 to PX4.

Referring to FIGS. 10 and 11C, the first wiring line 831 connected to the second pad PAD2 may be connected through a third contact AC3 to the active region ACT of the first pixel section PX1. For example, the active region ACT of the first pixel section PX1 may be connected in common to the floating diffusion regions FD of the first to fourth pixel section PX1 to PX4. For example, the reset transistor Rx may be constituted by the first gate pattern GEP1 and its underlying active region ACT of the first pixel section PX1.

Referring to FIG. 11A, the first wiring line 831 connected to the second pad PAD2 may be connected through a fourth contact AC4 to the fourth gate pattern GEP4 of the fourth pixel section PX4. For example, the fourth gate pattern GEP4 of the fourth pixel section PX4 may be connected in common to the floating diffusion regions FD of the first to fourth pixel sections PX1 to PX4. The driver transistor Dx may be constituted by the fourth gate pattern GEP4 and the active region ACT of the fourth pixel section PX4. For example, in an embodiment the driver transistor Dx may be a source follower transistor. The first wiring line 831 may be connected through a fifth contact AC5 to the active region ACT of the fourth pixel section PX4. Another first wiring line 831 may be connected through the fifth contact AC5 to the active region ACT of the first pixel section PX1.

FIG. 11C depicts by way of example a structure in which the second contact AC2 and the third contact AC3 are directly connected to each other through the first wiring line 831. However, embodiments of the present disclosure are not necessarily limited thereto. For example, in an embodiment the second contact AC2 and the third contact AC3 may be connected to each other through the first wiring line 831 and the second wiring line 832 that overlies the first wiring line 831.

A via VI may be disposed between the second wiring line 832 and the first wiring line 831. The first metal layer and the second metal layer may be connected to each other (e.g., electrically connected thereto) through the via VI.

A dielectric layer 400 may be disposed on the first surface 100a of the first substrate 100. A fence pattern 300 may be disposed on the dielectric layer 400. Color filters CF may be provided between grids of the fence pattern 300. In an embodiment, the color filters CF may include a microlens layer 500 having microlenses 510. The microlens 510 may correspondingly cover the first and fourth pixel sections PX1 to PX4. In some embodiments, one microlens 510 may cover the first and fourth pixel sections PX1 to PX4. However, embodiments of the present disclosure are not necessarily limited thereto.

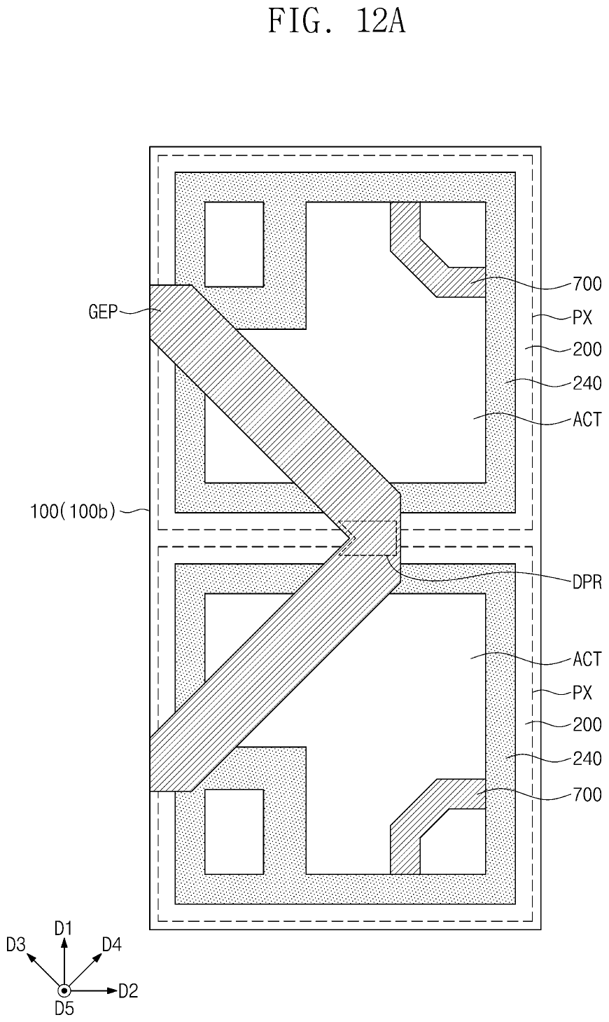

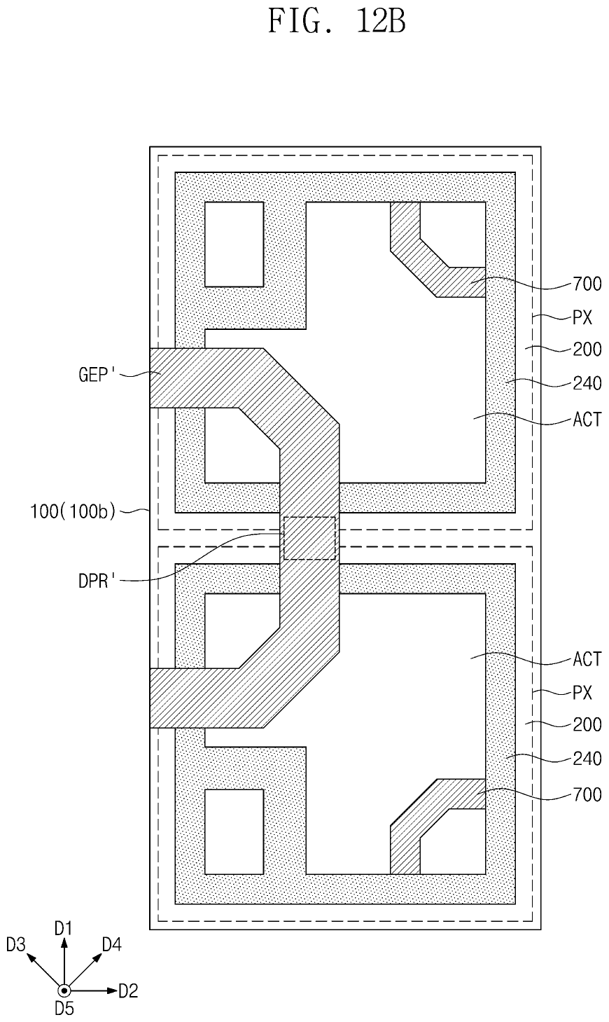

FIGS. 12A and 12B illustrate plan views of section M depicted in FIG. 3, showing a pixel different from that of an image sensor according to some embodiments of the present inventive concepts.

In comparison of the gate pattern GEP of FIG. 12A according to an embodiment of the present inventive concepts with a gate pattern GEP′ of FIG. 12B according to a comparative embodiment, each of the gate patterns GEP and GEP′ may extend from the active region ACT to the separation pattern 200 to vertically overlap the separation pattern 200. The gate pattern GEP of FIG. 12A may include a portion that vertically overlaps the separation pattern 200, which portion is called a first region DPR. The gate pattern GEP′ of FIG. 12B may include a portion that vertically overlaps the separation pattern 200, which portion is called a second region DPR′.

The first region DPR shown in FIG. 12A may have a trapezoidal shape when viewed in a plan view. The second region DPR′ shown in FIG. 12B may have a tetragonal shape when viewed in a plan view. The gate pattern GEP of FIG. 12A according to an embodiment of the present inventive concepts may have at least one line that linearly extends, and thus the first region DPR may have a trapezoidal shape. Therefore, each of the first region DPR and the second region DPR′ may have an area that vertically overlaps the separation pattern 200, and the area of the first region DPR may be less than that of the second region DPR′. The first region DPR may have one lateral surface including a sharp point.

For example, as shown in FIG. 12A, the gate pattern GEP may be formed to have a relatively small region that vertically overlaps the separation pattern 200, and thus it may be possible to reduce a rate of failure occurring in fabrication of an image sensor. In photolithography and etching processes for forming the gate pattern GEP in fabrication of an image sensor, it may be possible to reduce pattern defects that occur due to complexity of patterns.

According to an embodiment of the present inventive concepts, the gate pattern GEP of a driver transistor may have a first surface that linearly extends, and may be simultaneously formed on neighboring pixel sections PX. Therefore, there may be a relatively small region where the gate pattern GEP vertically overlaps the separation pattern 200, and a rate of failure may be less than that of an ordinary image sensor. A fabrication process for an image sensor may have increased efficiency and reduced failure rate, and thus the image sensor may increase in reliability.

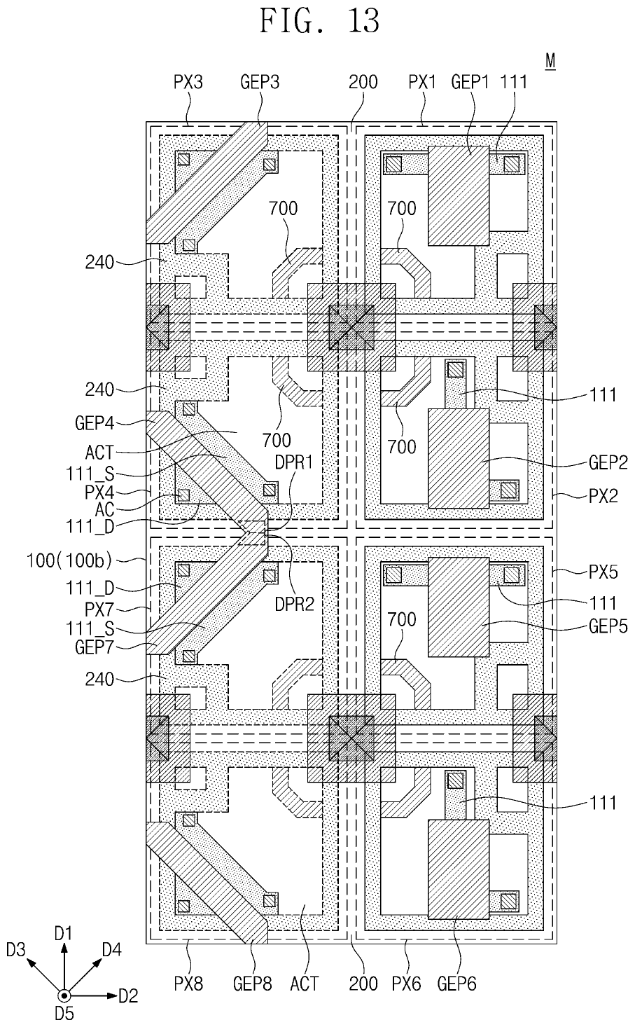

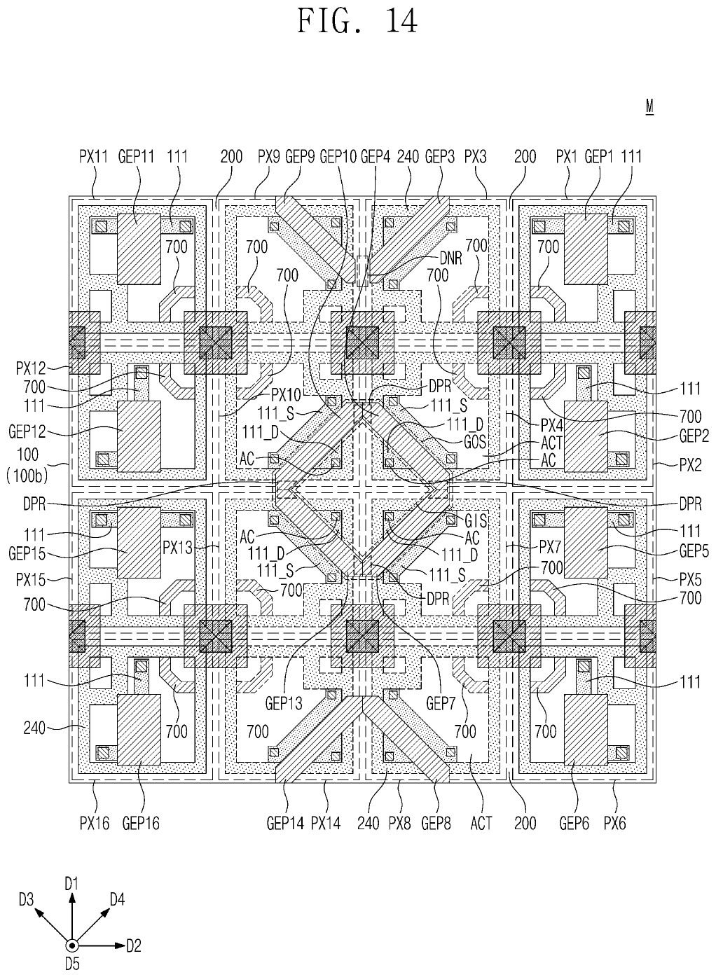

FIGS. 13 and 14 illustrate plan views showing pixels of an image sensor according to some embodiments of the present inventive concepts. In the embodiment that follows, a detailed description of technical features repetitive to those formerly discussed with reference to FIGS. 2 to 8B and 10 to 11C may be omitted, and differences thereof will be discussed in detail.

Referring to FIG. 13, an image sensor according to some embodiments of the present inventive concepts may include a plurality of pixel sections PX1 to PX8. For example, first and second pixel sections PX1 and PX2 may be disposed adjacent to each other in the first direction D1. Third and fourth pixel sections PX3 and PX4 may be disposed adjacent to each other in the first direction D1. Fifth and sixth pixel sections PX5 and PX6 may be disposed adjacent to each other in the first direction D1. Seventh and eighth pixel sections PX7 and PX8 may be disposed adjacent to each other in the first direction D1. The first and third pixel sections PX1 and PX3 may be disposed adjacent to each other in the second direction D2. The fifth and seventh pixel sections PX5 and PX7 may be disposed adjacent to each other in the second direction D2. For example, as shown in FIG. 13, in an embodiment an active pixel sensor array may include a plurality of pixels that are arranged in a 2×4 arrangement.

The separation pattern 200 and the device isolation pattern 240 may together constitute a separation structure. The separation structure may define the pixel sections PX1 to PX8, ground regions, the floating diffusion regions, and the active regions ACT. Each of the active regions ACT may include a first impurity region 111_D and a second impurity region 111_S that is spaced apart from the first impurity region 111_D (e.g., in the fourth direction D4). The first impurity region 111_D may be a drain region. The second impurity region 111_S may be a source region.

The active region ACT of each of the first to eighth pixel sections PX1 to PX8 may be disposed thereon with at least corresponding one of first to eighth gate patterns GEP1 to GEP8. One transistor may be constituted by one of the first to eighth gate patterns GEP1 to GEP8, the first impurity region 111_D, the second impurity region 111_S, and other impurity region 111 of the active region ACT. For example, the first impurity region 111_D, the second impurity region 111_S, other impurity region 111, and the gate patterns GEP1 to GEP8 may constitute at least one transistor selected from the driver transistor Dx, the reset transistor Rx, and the selection transistor Ax that are discussed with reference to FIG. 2. In an embodiment, the first to eighth gate patterns GEP1 to GEP8 may include a conductive material, such as a doped polysilicon.

Each of the first, second, fifth, and sixth gate patterns GEP1, GEP2, GEP5, and GEP6 may have a rectangular shape when viewed in a plan view. The third and seventh gate patterns GEP3 and GEP7 may extend along the fourth direction D4 from the separation pattern 200 through the device isolation pattern 240 and the active region ACT to another separation pattern 200. The fourth and eighth gate patterns GEP4 and GEP8 may extend along the third direction D3 from the separation pattern 200 through the device isolation pattern 240 and the active region ACT to another separation pattern 200. The third and fourth gate patterns GEP3 and GEP4 may have shapes that are symmetric to each other about the second direction D2, and likewise the seventh and eighth gate patterns GEP7 and GEP8 may have shapes that are symmetric to each other about the second direction D2.

The fourth gate pattern GEP4 may include a first pattern portion DRP1 that vertically overlaps the separation pattern 200. The seventh gate pattern GEP7 may include a second pattern portion DPR2 that vertically overlaps the separation pattern 200. The first pattern portion DPR1 and the second pattern portion DPR2 may be adjacent to each other on the separation pattern 200 (e.g., in the first direction D1). However, embodiments of the present disclosure are not necessarily limited thereto. For example, in an embodiment, the first pattern portion DPR1 and the second pattern portion DPR2 may not be adjacent to each other. For example, the fourth gate pattern GEP4 and the seventh gate pattern GEP7 may not be connected to each other and may be spaced apart from each other.

Each of the first and second pattern portions DPR1 and DPR2 may have a trapezoidal shape when viewed in a plan view. The first pattern portion DPR1 and the second pattern portion DPR2 may have shapes that are symmetric to each other along the first direction D1. When the first and second pattern portions DPR1 and DPR2 are adjacently connected to each other, one lateral surface may linearly extend and another lateral surface may include a sharp point. In an embodiment, the first and second pattern portions DPR1 and DPR2 may have the same planar area as each other.

Referring to FIG. 14, an image sensor according to some embodiments of the present inventive concepts may include a plurality of pixel sections PX1 to PX16. For example, first, second, fifth, and sixth pixel sections PX1, PX2, PX5, and PX6 may be sequentially disposed along the first direction D1. Third, fourth, seventh, and eighth pixel sections PX3, PX4, PX7, and PX8 may be sequentially disposed along the first direction D1. Ninth, tenth, thirteenth, and fourteenth pixel sections PX9, PX10, PX13, and PX14 may be sequentially disposed along the first direction D1. Eleventh, twelfth, fifteenth, and sixteenth pixel sections PX11, PX12, PX15, and PX16 may be sequentially disposed along the first direction D1.

The first, third, ninth, and eleventh pixel sections PX1, PX3, PX9, and PX11 may be sequentially disposed along the second direction D2. The second, fourth, tenth, and twelfth pixel sections PX2, PX4, PX10, and PX12 may be sequentially disposed along the second direction D2. The fifth, seventh, thirteenth, and fifteenth pixel sections PX5, PX7, PX13, and PX15 may be sequentially disposed along the second direction D2. The sixth, eighth, fourteenth, and sixteenth pixel sections PX6, PX8, PX14, and PX16 may be sequentially disposed along the second direction D2. For example, as shown in FIG. 14, in an embodiment an active pixel sensor array may include a plurality of pixels that are arranged in a 4×4 arrangement.

The separation pattern 200 and the device isolation pattern 240 may together constitute a separation structure. The separation structure may define the pixel sections PX1 to PX16, ground regions, the floating diffusion regions, and the active regions ACT. Each of the active regions ACT may include a first impurity region 111_D and a second impurity region 111_S that is spaced apart from the first impurity region 111_D (e.g., in the third or fourth directions D3, D4). The first impurity region 111_D may be a drain region. The second impurity region 111_S may be a source region.

The active region ACT of each of the first to sixteenth pixel sections PX1 to PX16 may be disposed thereon with at least corresponding one of first to sixteenth gate patterns GEP1 to GEP16. The first impurity region 111_D, the second impurity region 111_S, other impurity region 111, and the first to sixteenth gate patterns GEP1 to GEP16 may constitute at least one transistor selected from the driver transistor Dx, the reset transistor Rx, and the selection transistor Ax that are discussed with reference to FIG. 2. The first to sixteenth gate patterns GEP1 to GEP16 may include a conductive material (e.g., doped polysilicon).

In an embodiment, each of first, second, fifth, sixth, eleventh, fifteenth, and sixteenth gate patterns GEP1, GEP2, GEP5, GEP6, GEP11, GEP12, GEP15, and GEP16 may have a rectangular shape when viewed in a plan view. Each of third, seventh, tenth, and fourteenth gate patterns GEP3, GEP7, GEP10, and GEP14 may extend along the fourth direction D4 from the separation pattern 200 through the device isolation pattern 240 and the active region ACT to another separation pattern 200. Each of fourth, eighth, ninth, and thirteenth gate patterns GEP4, GEP8, GEP9, and GEP13 may extend along the third direction D3 from the separation pattern 200 through the device isolation pattern 240 and the active region ACT to another separation pattern 200. The third and fourth gate patterns GEP3 and GEP4 may have shapes that are symmetric to each other along the first direction D1, and this relationship may also be included with respect to the seventh and eighth gate patterns GEP7 and GEP8, the ninth and tenth gate patterns GEP9 and GEP10, and the thirteenth and fourteenth gate patterns GEP13 and GEP14.

The fourth, seventh, tenth, and thirteenth gate patterns GEP4, GEP7, GEP10, and GEP13 may be connected to each other on the separation pattern 200. There may be an overlapping region DPR that vertically overlaps the separation pattern 200. One lateral surface of the overlapping region DPR may linearly extend, and another lateral surface of the overlapping region DPR may include a sharp point. A combination of the fourth, seventh, tenth, and thirteenth gate patterns GEP4, GEP7, GEP10, and GEP13 that are connected to each other may include an inner surface GIS and an outer surface GOS. In an embodiment, the inner surface GIS may have a rhombic shape due to surfaces of the gate patterns GEP4, GEP7, GEP10, and GEP13 that are linearly connected to each other. The outer surface GOS may have an octagonal shape.

The eighth and fourteenth gate patterns GEP8 and GEP14 may be connected to each other on the separation pattern 200. The third and ninth gate patterns GEP3 and GEP9 may not be connected to each other on the separation pattern 200. For example, each of the third and ninth gate patterns GEP3 and GEP9 may include an overlapping region that vertically overlaps the separation pattern 200. There is also a non-overlapping region of the separation pattern 200 in which the separation pattern 200 does not vertically overlap the third and ninth gate patterns GEP3, GEP9. The non-overlapping region may be a non-overlapping region DNR. The non-overlapping region DNR may cause the third and ninth gate patterns GEP3 and GEP9 not to directly contact each other.

In an image sensor according to the present inventive concepts, it may be possible to reduce noise occurring in fabricating or operating the image sensor. In addition, a driver transistor may have a wider channel width relative to a channel length, and thus it may be possible to effectively suppress an effect of noise occurring at a separation pattern and a gate pattern of the driver transistor. A random noise phenomenon may therefore be reduced to increase performance of the image sensor.

In the image sensor according to an embodiment of the present inventive concepts, there may be a relatively small region where the separation pattern vertically overlaps the gate pattern of the driver transistor, and thus it may be possible to effectively perform a fabrication process for the image sensor. Moreover, the gate pattern (e.g., poly-silicon) disposed on the separation pattern may have a reduced area to decrease a failure rate of the image sensor. Accordingly, the image sensor may have increased reliability.

Although the present inventive concepts have been described in connection with some non-limiting embodiments thereof, it will be understood to those skilled in the art that various changes and modifications may be made without departing from the technical spirit and essential feature of the present inventive concepts.

What is claimed is:

1. An image sensor, comprising:
a substrate that includes a pixel section; and
a separation pattern disposed in the substrate, the separation pattern surrounding the pixel section,
wherein the separation pattern includes:
a first sub-separation pattern that extends in a first direction parallel to an upper surface of the substrate; and
a second sub-separation pattern that extends in a second direction that intersects the first direction and is parallel to the upper surface of the substrate,
wherein the pixel section includes:
a device isolation pattern that defines an active region in the pixel section; and
at least one gate pattern on the active region,
wherein the at least one gate pattern extends along a third direction from the first sub-separation pattern through the active region and the device isolation pattern to the second sub-separation pattern, the third direction intersecting the first direction and the second direction and parallel to the upper surface of the substrate,
wherein the at least one gate pattern has a first surface and a second surface that are opposite to each other,
wherein the first surface extends linearly from the first sub-separation pattern to the second sub-separation pattern.

2. The image sensor of claim 1, wherein:
the second surface includes a first sub-surface that extends along the third direction, a second sub-surface that extends along the second direction, and a third sub-surface that extends along the first direction, and
the second surface extends from the first sub-separation pattern to the second sub-separation pattern.

3. The image sensor of claim 2, wherein the first sub-surface is parallel to the first surface.

4. The image sensor of claim 1, wherein:
the at least one gate pattern includes a first portion, a second portion, and a third portion disposed along the third direction;
the second portion extends from the first sub-separation pattern to the active region;
the third portion extends from the second sub-separation pattern to the active region; and
wherein the first portion is interposed between the second portion and the third portion, the first portion directly contacting the second portion and the third portion on the active region.

5. The image sensor of claim 4, wherein:
a length of the first portion in the third direction is equal to a first distance;
a length of the first portion in a fourth direction that intersects the third direction and is parallel to the upper surface of the substrate is equal to a second distance; and
the first distance is greater than the second distance.

6. The image sensor of claim 5, wherein:
the active region includes a first impurity region and a second impurity region spaced apart from the first impurity region;
the pixel section includes at least one transistor,
the at least one transistor includes:
the first and second impurity regions; and
the at least one gate pattern between the first impurity region and the second impurity region,
wherein an effective channel length of the transistor is equal to the second distance, and
wherein an effective channel width of the transistor is equal to the first distance.

7. The image sensor of claim 6, wherein the at least one transistor is a source follower transistor.

8. The image sensor of claim 1, wherein:
the substrate has a first surface and a second surface opposite to the first surface;
the active region is adjacent to the second surface of the substrate; and
the substrate further includes a photoelectric conversion region in the substrate.

9. The image sensor of claim 8, further comprising:
a color filter on the first surface of the substrate; and
a microlens on the color filter.

10. The image sensor of claim 1, further comprising a buried gate pattern on the active region,
wherein the active region further includes a floating diffusion region adjacent to the buried gate pattern, and
wherein the buried gate pattern extends into the substrate.

11. The image sensor of claim 6, further comprising:
a first active contact directly connected to the first impurity region; and
a second contact directly connected to the second impurity region.

12. An image sensor including a pixel section, wherein the pixel section includes:
an active region in the pixel section, the active region including a first impurity region and a second impurity region; and
a gate pattern on the active region, the gate pattern having a first surface and a second surface that are opposite to each other,
wherein the gate pattern is between the first impurity region and the second impurity region,
wherein the first surface is close to the first impurity region and extends linearly, and
wherein an area of the first impurity region is less than an area of the second impurity region.

13. The image sensor of claim 12, wherein the second surface is close to the second impurity region, the second impurity region including a first sub-surface, a second sub-surface, and a third sub-surface, the second impurity region further including a first corner where the first sub-surface and the second sub-surface meet each other and a second corner where the first sub-surface and the third sub-surface meet each other.

14. The image sensor of claim 12, wherein the second impurity region includes:
a first edge region that extends in a first direction; and
a second edge region that extends in a second direction that intersects the first direction.

15. The image sensor of claim 14, further comprising:
a first active contact on the first impurity region; and
a second active contact on the second impurity region,
wherein the second active contact is on the first edge region or the second edge region.

16. The image sensor of claim 15, wherein the second active contact is on a central portion of the second impurity region.

17. An image sensor, comprising:
a substrate that includes a plurality of pixel sections; and
a separation pattern in the substrate and positioned between adjacent pixels of the plurality of pixel sections,
wherein the separation pattern includes:
a first sub-separation pattern that extends in a first direction parallel to an upper surface of the substrate; and
a second sub-separation pattern that extends in a second direction that intersects the first direction and is parallel to the upper surface of the substrate,
wherein the plurality of pixel sections include:
a first pixel section and a second pixel section that are adjacent to each other in the first direction;
a third pixel section adjacent to the first pixel section in the second direction; and
a fourth pixel section adjacent to the second pixel section in the second direction and adjacent to the third pixel section in the first direction,
wherein each of the first to fourth pixel sections includes;
a device isolation pattern that defines an active region in the first to fourth pixel sections; and
a transistor that corresponds to each of the first to fourth pixel sections,
wherein the active region includes a first impurity region and a second impurity region spaced apart from each other, the active region comprising first to fourth active regions in the first to fourth pixel sections, respectively,
wherein the transistor includes:
the first impurity region;
the second impurity region; and
a gate pattern between the first impurity region and the second impurity region, the gate pattern comprising first to fourth gate patterns disposed in the first to fourth pixel sections, respectively,
wherein the first gate pattern and the fourth gate pattern extend along a third direction from the first sub-separation pattern to the second sub-separation pattern, the third direction intersecting each of the first direction and the second direction and parallel to the upper surface of the substrate,
wherein the second gate pattern and the third gate pattern extend along a fourth direction from the second sub-separation pattern to the first sub-separation pattern, the fourth direction intersecting the first to third directions and parallel to an upper surface of the substrate,
wherein the first to fourth gate patterns are in direct contact with each other on the separation pattern, and
wherein a combination of the first to fourth gate patterns in direct contact with each other has an inner surface having a rhombic shape and an outer surface having an octagonal shape.

18. The image sensor of claim 17, further comprising a fifth pixel section and a sixth pixel section that are adjacent to each other, each of the fifth and sixth pixel sections including a gate pattern, the gate pattern comprising fifth and sixth gate patterns in the fifth and sixth pixel sections, respectively,
wherein the fifth gate pattern and the sixth gate pattern are not in direct contact with each other on the separation pattern.

19. The image sensor of claim 17, wherein the substrate has a first surface and a second surface opposite to the first surface and further includes a photoelectric conversion region in the substrate, the first to fourth active regions are adjacent to the second surface,
wherein the image sensor further comprises:
a color filter on the first surface of the substrate; and
a microlens on the color filter,
wherein the plurality of pixel sections further include:
a buried gate pattern on each of the first to fourth active regions; and
a floating diffusion region adjacent to the buried gate pattern.

20. The image sensor of claim 19, wherein the substrate further includes a ground region in the substrate,
wherein the image sensor further comprises:
a pad on the ground region and connected through a first contact; and
a plurality of metal layers that are stacked on the substrate,
wherein a wiring line in the plurality of metal layers is electrically connected to the gate pattern through a second contact.
